(19) United States
(12) Patent Application Publication
(10) Pub. No.: US 2016/0099398 A1
(43) Pub. Date: Apr. 7, 2016

(54) THERMOELECTRIC GENERATORS FOR RECOVERING WASTE HEAT FROM ENGINE EXHAUST, AND METHODS OF MAKING AND USING SAME

(71) Applicant: Alphabet Energy, Inc., Hayward, CA (US)

(72) Inventors: Adam Lorimer, Walnut Creek, CA (US); Ad de Pijper, Walnut Creek, CA (US); Christopher Hannemann, Berkeley, CA (US); Douglas Crane, Richmond, CA (US); Sasi Bhushan Beera, Fremont, CA (US); Sravan Kumar R. Sura, Fremont, CA (US); Jordan Chase, Oakland, CA (US); Mothusi Pahl, Oakland, CA (US); Tapan Patel, San Francisco, CA (US); Matthew L. Scullin, San Francisco, CA (US); Michael Stephen Lindheim, Oakland, CA (US); Daniel Freeman, San Jose, CA (US); Mark Frederic Melikian, Redwood City, CA (US); Luna P. Schector, Oakland, CA (US)

(21) Appl. No.: 14/872,898

(22) Filed: Oct. 1, 2015

Related U.S. Application Data
(60) Provisional application No. 62/059,092, filed on Oct. 2, 2014.
(60) Provisional application No. 62/059,084, filed on Oct. 2, 2014.

(51) Int. Cl. H01L 35/30; H01L 35/32

(52) U.S. Cl. CPC H01L 35/30; H01L 35/32

(57) ABSTRACT

A thermoelectric generator includes a tapered inlet manifold including first and second non-parallel sides; first and second pluralities of outlet manifolds; and thermoelectric generating units (TGUs) each including a hot-side heat exchanger (HHX) with inlet and outlet; a cold-side heat exchanger (CHX); and thermoelectric devices arranged between the HHX and CHX. The inlets of some of the HHXs receive exhaust gas from the first side of the tapered inlet manifold and the outlets of those HHXs are coupled to outlet manifolds of the first plurality of outlet manifolds. The inlets of other of the HHXs receive exhaust gas from the second side of the tapered inlet manifold and the outlets of those HHXs are coupled to outlet manifolds of the second plurality of outlet manifolds. The thermoelectric devices can generate electricity responsive to a temperature differential between the exhaust gas and the CHXs.

### CROSS-REFERENCE TO RELATED APPLICATIONS

This application claims the benefit of U.S. Provisional Patent Application No. 62/059,092, filed on Oct. 2, 2014 and entitled “THERMOELECTRIC GENERATORS FOR RECOVERING WASTE HEAT FROM ENGINE EXHAUST, AND METHODS OF MAKING AND USING SAME,” the entire contents of which are incorporated by reference herein.

This application also claims the benefit of U.S. Provisional Patent Application No. 62/059,084, filed on Oct. 2, 2014 and entitled “THERMOELECTRIC GENERATING UNIT AND METHODS OF MAKING AND USING THE SAME,” the entire contents of which are incorporated by reference herein.

This application also is related to U.S. patent application No. (TBA), filed on even date herewith and entitled “THERMOELECTRIC GENERATING UNIT AND METHODS OF MAKING AND USING THE SAME,” the entire contents of which are incorporated by reference herein.

### FIELD

The present application is directed to thermoelectric generators. It would be recognized that the invention has a much broader range of applicability.

### BACKGROUND

Thermoelectric (TE) devices are often packaged using a plurality of thermoelectric legs arranged in multiple serial chain configurations on a base structure. Each of the plurality of thermoelectric legs can include either p-type or n-type thermoelectric material, which can be characterized by high electrical conductivity and relatively high thermal resistivity. One or more p-type TE legs can be pairwise-coupled to one or more n-type TE legs via a conductor from each direction in a serial chain or electrically in series-thermally in parallel or electrically in parallel-thermally in parallel configuration, one conductor being coupled at one end region of the TE leg and another conductor being coupled at another end region of the TE leg. When a bias voltage is applied across the top/bottom regions of the thermoelectric device using the two conductors as two electrodes, a temperature difference is generated so that the thermoelectric device can be used as a refrigeration (e.g., Peltier) device. When the thermoelectric device is subjected to a thermal junction with conductors at first end regions of the TE legs being attached to a cold side of the junction and conductors at second end regions of the TE legs being in contact with a hot side of the junction, the thermoelectric device is able to generate electrical voltage across the junction as an energy conversion (e.g., Seebeck) device.

The energy conversion efficiency of thermoelectric devices can be measured by a so-called thermal power density or “thermoelectric figure of merit” ZT, where ZT is equal to TS² σ/k where T is the temperature, S the Seebeck coefficient, σ the electrical conductivity, and k the thermal conductivity of the thermoelectric material. In order to drive up the value of ZT of thermoelectric devices utilizing the Seebeck effect, searching for high performance thermoelectric materials and developing low cost manufacturing processes are major concerns. However, new material combinations and new environmental requirements reveal the needs of improved techniques for utilizing thermoelectric devices.

### SUMMARY

The present application is directed to thermoelectric generators. It would be recognized that the invention has a much broader range of applicability.

Under one aspect, a thermoelectric generator includes a tapered inlet manifold configured to be coupled to an exhaust gas source. The tapered inlet manifold can include a first side defining a first outer surface of the tapered inlet manifold; and a second side defining a second outer surface of the tapered inlet manifold, the first side and the second side being arranged non-parallel to one another. The thermoelectric generator further can include a first plurality of outlet manifolds; a second plurality of outlet manifolds; and a plurality of thermoelectric generating units. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. A first subset of the thermoelectric generating units can be coupled to the first side of the tapered inlet manifold such that the inlet of the hot-side heat exchanger of each thermoelectric generating unit of the first subset receives exhaust gas from the first side of the tapered inlet manifold and the outlet of that hot-side heat exchanger is coupled to an outlet manifold of the first plurality of outlet manifolds. A second subset of the thermoelectric generating units can be coupled to the second side of the tapered inlet manifold such that the hot-side heat exchanger of each thermoelectric generating unit of the second subset receives exhaust gas from the second side of the tapered inlet manifold and the outlet of that hot-side heat exchanger is coupled to an outlet manifold of the second plurality of outlet manifolds. The thermoelectric devices of the plurality of thermoelectric generating units can generate electricity responsive to a temperature differential between the exhaust gas and the first cold-side heat exchangers.

In some embodiments, the generator includes a sufficient number of the thermoelectric generating units to generate at least about 5 kW of electricity based on the exhaust gas having a temperature between 400° C.-600° C. and a mass flow of the exhaust gas of between 500-1500 g/s.

In some embodiments, the first side and the second side of the tapered inlet manifold are arranged at an angle of between about 5 and 15 degrees relative to one another.

In some embodiments, the hot-side heat exchanger of each of the thermoelectric generating units includes a plurality of discrete channels, each of the discrete channels receiving the exhaust gas.

In some embodiments, a plurality of the outlets of the hot-side heat exchangers of the thermoelectric generating units of the first subset are coupled to one outlet manifold of the first plurality of outlet manifolds; and a plurality of the outlets of the hot-side heat exchangers of the thermoelectric generating units of the second subset are coupled to one outlet manifold of the second plurality of outlet manifolds. In some embodiments, four of the outlets of the hot-side heat exchangers of the thermoelectric generating units of the first subset are coupled to one outlet manifold of the first plurality of outlet manifolds; and four of the outlets of the hot-side heat exchangers of the thermoelectric generating units of the second subset are coupled to one outlet manifold of the second plurality of outlet manifolds.

In some embodiments, each of the first cold-side heat exchangers is coupled to a coolant system configured to pump a coolant through the first cold-side heat exchangers.

Some embodiments further include a diverter valve configured so as to selectably divert a flow of the exhaust gas away from the plurality of thermoelectric generating units.

Some embodiments, further include a single shipping container housing the tapered inlet manifold, the first plurality of outlet manifolds, the second plurality of outlet manifolds, the plurality of thermoelectric generating units, one or more radiators, and power electronics.

In some embodiments, each thermoelectric generating unit further includes a second cold-side heat exchanger; and a second plurality of thermoelectric devices arranged between the hot-side heat exchanger and the second cold-side heat exchanger.

Some embodiments further include at least one inverter receiving the electricity from the thermoelectric devices, wherein the electricity generated by the thermoelectric devices is DC electricity, wherein the at least one inverter converts the DC electricity to AC electricity.

In some embodiments, a first plurality of apertures are defined through the first side and a second plurality of apertures are defined through the second side. In some embodiments, the inlets of the hot-side heat exchangers of the first subset of the thermoelectric generating units receive the exhaust gas through the first plurality of apertures, and the inlets of the hot-side heat exchangers of the second subset of the thermoelectric generating units receive the exhaust gas through the second plurality of apertures. In some embodiments, the apertures of the first and second pluralities of apertures are substantially rectangular.

In some embodiments, the tapered inlet manifold further includes a splitter disposed within the tapered inlet manifold and arranged between the first side and the second side. In some embodiments, a plurality of apertures are defined through the splitter. In some embodiments, the apertures are substantially circular. In some embodiments, the splitter is arranged so as approximately to bisect an angle between the first side and the second side.

Some embodiments further include a diesel oxidation catalyst disposed between the exhaust gas source and the tapered inlet manifold.

In some embodiments, each hot-side heat exchanger includes at least one threaded rod sealingly coupling the hot-side heat exchanger to the inlet manifold.

Under another aspect, a method of generating electricity includes receiving exhaust gas by a tapered inlet manifold. The tapered inlet manifold can include a first side defining a first outer surface of the tapered inlet manifold; and a second side defining a second outer surface of the tapered inlet manifold, the first side and the second side being arranged non-parallel to one another. The method further can include outputting by the tapered inlet manifold the exhaust gas to a plurality of thermoelectric generating units. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. The method further can include receiving, by the inlets of the hot-side heat exchangers of a first subset of the thermoelectric generating units, exhaust gas from the first side of the tapered inlet manifold and outputting the exhaust gas, by the outlets of those hot-side heat exchangers, to an outlet manifold of a first plurality of outlet manifolds. The method further can include receiving, by the inlets of the hot-side heat exchangers of a second subset of the thermoelectric generating units, exhaust gas from the second side of the tapered inlet manifold and outputting the exhaust gas, by the outlets of those hot-side heat exchangers, to an outlet manifold of a second plurality of outlet manifolds. The method further can include generating electricity by the thermoelectric devices of the plurality of thermoelectric generating units responsive to a temperature differential between the exhaust gas and the first cold-side heat exchangers of those thermoelectric generating units.

Some embodiments include generating at least about 5 kW of electricity based on the exhaust gas having a temperature between 400° C.-600° C. and a mass flow of the exhaust gas of between 500-1500 g/s.

In some embodiments, the first side and the second side of the tapered inlet manifold are arranged at an angle of between about 5 and 15 degrees relative to one another.

In some embodiments, the hot-side heat exchanger of each of the thermoelectric generating units includes a plurality of discrete channels, each of the discrete channels receiving the exhaust gas.

In some embodiments, a plurality of the outlets of the hot-side heat exchangers of the thermoelectric generating units of the first subset output the exhaust gas to one outlet manifold of the first plurality of outlet manifolds; and a plurality of the outlets of the hot-side heat exchangers of the thermoelectric generating units of the second subset output the exhaust gas to one outlet manifold of the second plurality of outlet manifolds. In some embodiments, four of the outlets of the hot-side heat exchangers of the thermoelectric generating units of the first subset output the exhaust gas to one outlet manifold of the first plurality of outlet manifolds; and four of the outlets of the hot-side heat exchangers of the thermoelectric generating units of the second subset output the exhaust gas to one outlet manifold of the second plurality of outlet manifolds.

Some embodiments further include pumping a coolant through each of the first cold-side heat exchangers.

Some embodiments further include selectably diverting a flow of the exhaust gas away from the plurality of thermoelectric generating units.

Some embodiments further include housing the tapered inlet manifold, the first plurality of outlet manifolds, the second plurality of outlet manifolds, the plurality of thermoelectric generating units, one or more radiators, and power electronics in a single shipping container.

In some embodiments, each thermoelectric generating unit includes a second cold-side heat exchanger; and a second plurality of thermoelectric devices arranged between the hot-side heat exchanger and the second cold-side heat exchanger, the method further including generating electricity responsive to a temperature differential between the exhaust gas and the second cold-side heat exchangers.

Some embodiments further include receiving the electricity from the thermoelectric devices by at least one inverter, wherein the electricity generated by the thermoelectric devices is DC electricity, wherein the at least one inverter converts the DC electricity to AC electricity.

In some embodiments, a first plurality of apertures are defined through the first side and a second plurality of apertures are defined through the second side. In some embodiments, the inlets of the hot-side heat exchangers of the first subset of the thermoelectric generating units receive the exhaust gas through the first plurality of apertures, and the inlets of the hot-side heat exchangers of the second subset of the thermoelectric generating units receive the exhaust gas through the second plurality of apertures. In some embodiments, the apertures of the first and second pluralities of apertures are substantially rectangular.

In some embodiments, the tapered inlet manifold further includes a splitter disposed within the tapered inlet manifold and arranged between the first side and the second side. In some embodiments, a plurality of apertures are defined through the splitter. In some embodiments, the apertures are substantially circular. In some embodiments, the splitter is arranged so as approximately to bisect an angle between the first side and the second side.

Some embodiments further include cracking higher hydrocarbons in diesel exhaust using a diesel oxidation catalyst disposed between the exhaust gas source and the tapered inlet manifold.

In some embodiments, each hot-side heat exchanger includes at least one threaded rod sealingly coupling the hot-side heat exchanger to the inlet manifold.

### BRIEF DESCRIPTION OF DRAWINGS

FIGS. 1A-1B schematically illustrate views of an exemplary thermoelectric generator, according to some embodiments.

FIG. 2 schematically illustrates certain components of an exemplary thermoelectric generator, according to some embodiments.

FIGS. 3A-3B schematically illustrate views of exemplary components of a thermoelectric system for use in a thermoelectric generator such as illustrated in FIGS. 1A-1B and 2, according to some embodiments.

FIG. 4 illustrates steps in an exemplary method for generating electricity using a thermoelectric generator, according to some embodiments.

FIGS. 5A-5D schematically illustrate views of exemplary components of a thermoelectric system for use in a thermoelectric generator such as illustrated in FIGS. 1A-1B and 2, according to some embodiments.

FIGS. 6A-6B illustrate plots of exemplary normalized velocity at different portions of the exemplary thermoelectric system illustrated in FIGS. 5A-5D.

FIG. 7A illustrates a plot of exemplary power as a function of exhaust flow rate and inlet temperature through a thermoelectric generator such as illustrated in FIGS. 1A-1B and 2, according to some embodiments.

FIG. 7B illustrates a plot of exemplary power as a function of ambient and exhaust inlet temperature for a thermoelectric generator such as illustrated in FIGS. 1A-1B and 2, according to some embodiments.

FIG. 8 illustrates a plot of measured net power as a function of time for a thermoelectric generator such as illustrated in FIGS. 1A-1B and 2, according to some embodiments.

FIG. 9 illustrates an exemplary inverter system for use with a thermoelectric generator such as illustrated in FIGS. 1A-1B and 2, according to some embodiments.

FIGS. 10A-10G schematically illustrate views of an exemplary thermoelectric generating unit that optionally can be used with a thermoelectric generator such as illustrated in FIGS. 1A-1B and 2, according to some embodiments.

FIGS. 11A-11C schematically illustrate views of an exemplary thermoelectric assembly for use in a thermoelectric generating unit such as illustrated in FIGS. 10A-10G that optionally can be used with a thermoelectric generator such as illustrated in FIGS. 1A-1B and 2, according to some embodiments.

FIGS. 12A-12C schematically illustrate exemplary arrangements of fasteners for use in a thermoelectric generating unit such as illustrated in FIGS. 10A-10G that optionally can be used with a thermoelectric generator such as illustrated in FIGS. 1A-1B and 2, according to some embodiments.

FIG. 13A schematically illustrates one nonlimiting example of an arrangement of fasteners for use in a thermoelectric generating unit such as illustrated in FIGS. 10A-10G that optionally can be used with a thermoelectric generator such as illustrated in FIGS. 1A-1B and 2, according to some embodiments.

FIG. 13B schematically illustrates one nonlimiting example of a distribution of pressures that can be obtained using the arrangement of fasteners illustrated in FIG. 13A.

FIG. 14 illustrates a plot of exemplary power output as a function of exhaust flow for a thermoelectric generating unit such as illustrated in FIGS. 10A-10G that optionally can be used with a thermoelectric generator such as illustrated in FIGS. 1A-1B and 2, according to some embodiments.

FIG. 15 illustrates a plot of exemplary pressure drop as a function of exhaust flow for a thermoelectric generating unit such as illustrated in FIGS. 10A-10G that optionally can be used with a thermoelectric generator such as illustrated in FIGS. 1A-1B and 2, according to some embodiments.

FIG. 16 schematically illustrates steps in an exemplary method of preparing a thermoelectric generating unit that optionally can be used with a thermoelectric generator such as illustrated in FIGS. 1A-1B and 2, according to some embodiments.

### DETAILED DESCRIPTION

The present application is directed to thermoelectric generators. It would be recognized that the invention has a much broader range of applicability.

According to some embodiments, a thermoelectric generator (TEG) system can be used to recover waste heat from the exhaust gas of a generator, for example, a relatively large (e.g., >500 kW) stationary generator (genset—e.g., based on combustion of diesel or natural gas) such as can be used for mining, military, remote utility, or oil and gas applications. However, it should be understood that the present TEG suitably can be adapted for use with any engine that produces exhaust gas. In some embodiments, waste heat in the exhaust gas can be converted to electricity, e.g., direct current electricity. In some embodiments, such electricity conversion can provide a reduction in fuel usage, for example, a reduction of >1%.

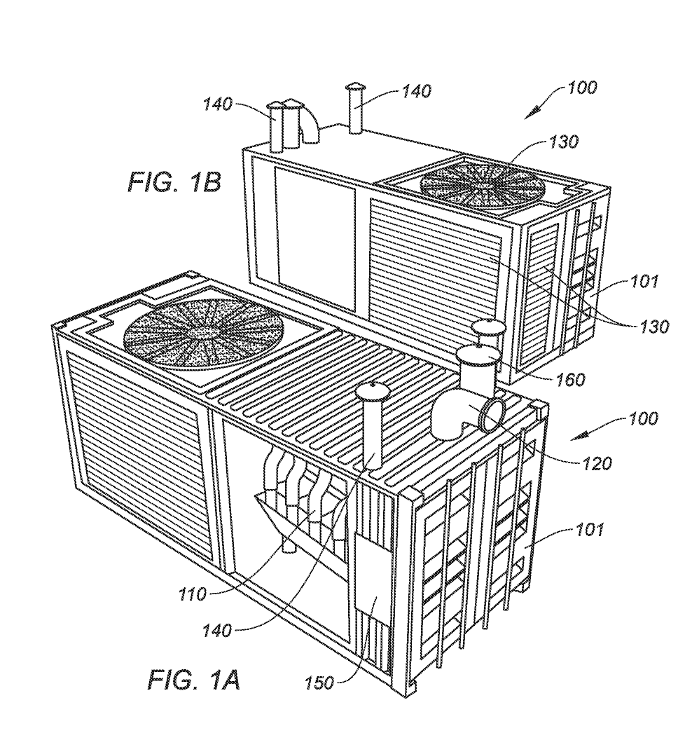

FIGS. 1A-1B schematically illustrate views of an exemplary thermoelectric generator, according to some embodiments. In the non-limiting embodiment illustrated in FIGS. 1A-1B, generator 100 can include a single shipping container 101 housing a plurality of components for use in generating electricity based on waste heat in a fluid, e.g., an exhaust gas from an engine. In some embodiments, the shipping container can be of standard dimensions, e.g., can include an intermodal freight container that can have industry standard dimensions, e.g., a length of about 20 feet, a width of about 8 feet, and a height between about 4 feet three inches (which can be referred to as “half height”) and about 9 feet six inches (which can be referred to as “high cube”), e.g., a height of about 8 feet six inches (which can be referred to as a “twenty-foot equivalent unit,” or TEU). However, it should be understood that the components of generator 100 suitably can be provided in any type of housing or plurality of housings, and indeed can omit a housing entirely. As used herein, the terms “about” and “approximately” are intended to mean within plus or minus ten percent of the stated value.

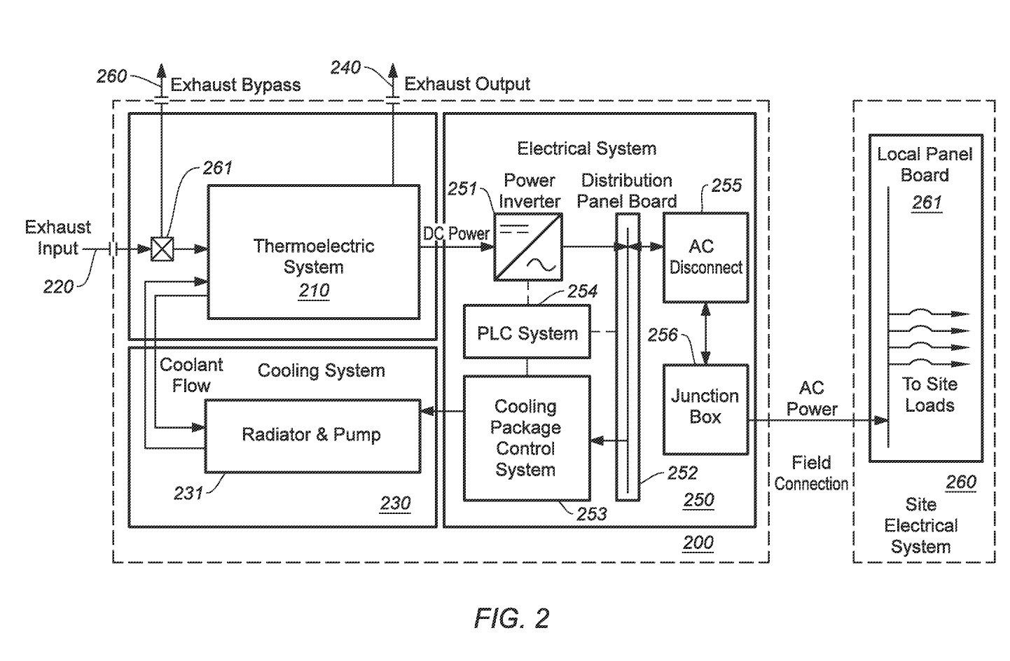

In some embodiments, generator 100 can include thermoelectric system 110, which can include a tapered inlet manifold, a first plurality of outlet manifolds, a second plurality of outlet manifolds, and a plurality of thermoelectric generating units (which also can be referred to as TEG generating units or modules) such as described in greater detail herein, e.g., with reference to FIGS. 2, 3A-3B, and 5A-5D, and which can be housed within shipping container 101. Generator 100 also can include inlet piping 120 via which thermoelectric system 110 can be coupled to a source of a fluid that carries waste heat, e.g., an engine producing exhaust. As illustrated in FIGS. 1A-1B, inlet piping 120 optionally can be partially housed within shipping container 101 and can extend beyond shipping container 101 so as to facilitate connection to the source of the fluid carrying waste heat. Generator 100 also can include one or more radiators 130, which can be coupled to the plurality of thermoelectric generating units so as to facilitate cooling of cold-side heat exchangers therein such as described elsewhere herein, and which can be housed within shipping container 101. Generator 100 also can include outlet piping 140 coupled to thermoelectric system 110, e.g., to one or both of the first plurality of outlet manifolds and second plurality of outlet manifolds of thermoelectric system 110, and configured to output the fluid after waste heat is extracted therefrom using thermoelectric system 110. Outlet piping 140 optionally can be partially housed within shipping container 101 and can extend beyond shipping container 101 so as to facilitate removal of the fluid from generator 100. Generator 100 also can include power electronics 150, which can be configured as described herein with reference to FIG. 2 and can provide electricity to suitable components of generator 100 and can receive electricity from thermoelectric system 110. Generator 100 further can include diverter outlet piping 160 coupled to inlet piping 120 and a diverter valve (not specifically illustrated) configured so as to selectably divert a flow of the exhaust gas received by inlet piping 120 away from the plurality of thermoelectric generating units under certain circumstances and into diverter outlet piping 160, e.g., circumstances in which it is desired not to provide the fluid to thermoelectric system 110.

In some embodiments, generator 100 further can include a diesel oxidation catalyst disposed between the exhaust gas source and the tapered inlet manifold. For example, in embodiments in which the fluid carrying the waste heat is exhaust gas from a diesel engine, such a diesel oxidation catalyst can reduce or inhibit deposition of exhaust components onto internal components of generator 100. For example, diesel exhaust can include higher hydrocarbons, which can become deposited inside of the hot-side heat exchangers of the thermoelectric generation units responsive to cooling of that exhaust by the heat exchangers. The diesel oxidation catalyst can crack the higher hydrocarbons and make components of the exhaust less “sticky” so as to reduce or inhibit deposition of the higher hydrocarbons within the hot-side heat exchangers even as those heat exchangers cool the exhaust gas.

FIG. 2 schematically illustrates certain components of an exemplary thermoelectric generator, according to some embodiments. In some embodiments, thermoelectric generator 200 illustrated in FIG. 2 can be fully or partially disposed within a housing, e.g., a shipping container, in a manner such as described above with reference to FIGS. 1A-1B. In some embodiments, generator 200 can include thermoelectric system 210, which can include a tapered inlet manifold, a first plurality of outlet manifolds, a second plurality of outlet manifolds, and a plurality of thermoelectric generating units such as described in greater detail herein, e.g., with reference to FIGS. 1A-1B, 3A-3B, and 5A-5D. Generator 200 also can include inlet piping 220 via which thermoelectric system 210 can be coupled to a source of a fluid that carries waste heat, e.g., an engine producing exhaust. Generator 200 also can include one or more radiators 231, which can be coupled to the plurality of thermoelectric generating units so as to facilitate cooling of cold-side heat exchangers therein. For example, a pump 231 can circulate coolant to, through, and from the cold-side heat exchangers of the thermoelectric generating units of thermoelectric system 210, and can circulate that coolant through radiator 231 so as to remove heat from system 210. For example, each of the cold-side heat exchangers of thermoelectric system 210 can be coupled to coolant system 230 configured to pump a coolant through the cold-side heat exchangers, e.g., using pump 231.

Generator 200 also can include outlet piping 240 coupled to thermoelectric system 210, e.g., to one or both of the first plurality of outlet manifolds and second plurality of outlet manifolds of thermoelectric system 210, and configured to output the fluid after waste heat is extracted therefrom using thermoelectric system 210. Outlet piping 240 optionally can be partially housed within shipping container 201 and can extend beyond shipping container 201 so as to facilitate removal of the fluid from generator 200. Generator 200 also can include power electronics 250, which can be configured to provide electricity to suitable components of generator 200 and can receive electricity from thermoelectric system 210. Generator 200 further can include diverter outlet piping 260 coupled to inlet piping 220 and diverter valve 261 configured so as to selectably divert a flow of the exhaust gas received by inlet piping 220 away from the plurality of thermoelectric generating units under certain circumstances, e.g., circumstances in which it is desired not to provide the fluid to thermoelectric system 210. In some embodiments, the state of diverter valve 261 can be controlled by PLC system 254.

Still referring to FIG. 2, power electronics 250 can include at least one power inverter 251, distribution panel board 252, cooling package control system 253, programmable logic control (PLC) system 254, AC disconnect 255, and junction box 256. The at least one power inverter 251 is coupled to thermoelectric system 210 so as to receive electricity therefrom, e.g., receiving electricity from the thermoelectric devices responsive to a temperature differential between the hot-side heat exchanger and the cold-side heat exchanger. The electricity generated by the thermoelectric devices can be DC electricity, and the at least one power inverter 251 can convert the DC electricity to AC electricity. Power inverter 251 can be coupled to distribution panel board 252, which can be configured so as to distribute the AC electricity to an external load, e.g., to site electrical system 260. In some embodiments, distribution panel board 252 can be coupled to external local panel board 261 of site electrical system 260 via AC disconnect 255 and junction box 256. AC disconnect 255 can be used so as to selectably decouple distribution panel board 252 from site electrical system 260, e.g., if it is desired to stop providing AC electricity from generator 200 to site electrical system 260 or other load. Distribution panel board 252 also can be configured so as to distribute the AC electricity to one or more internal components of generator 200. For example, suitable wiring can be provided so as to connect distribution panel board to one or more of cooling package control system 253, PLC system 254, and radiator and pump 231 so as to provide AC electricity thereto.

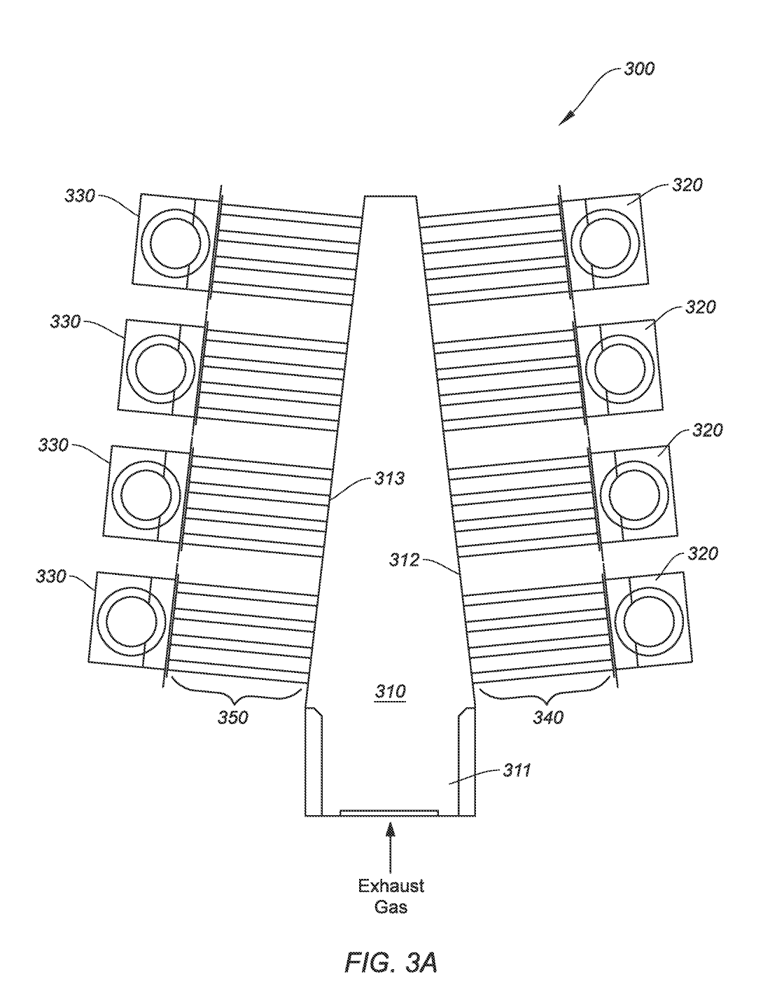

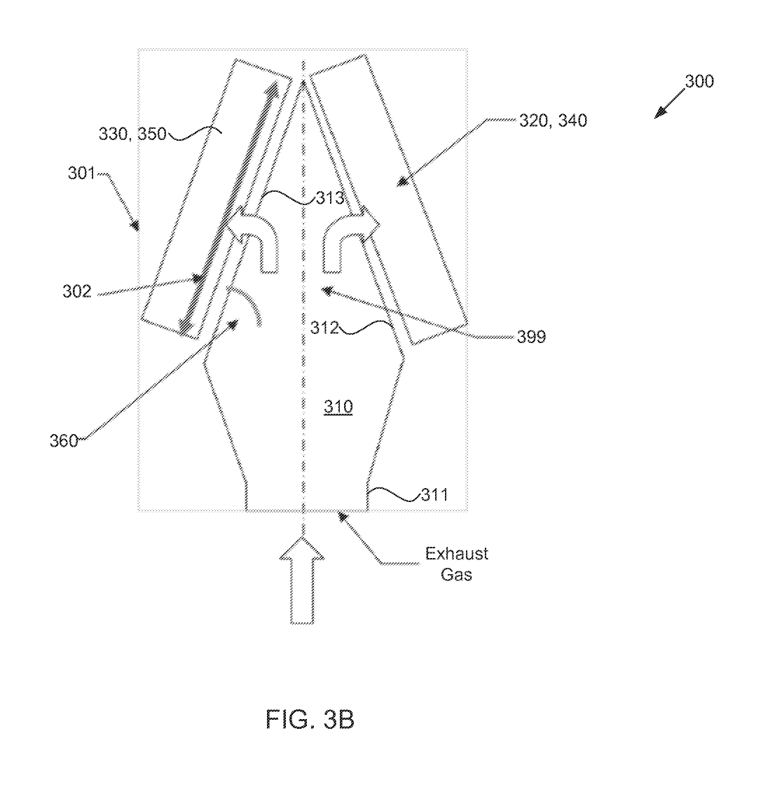

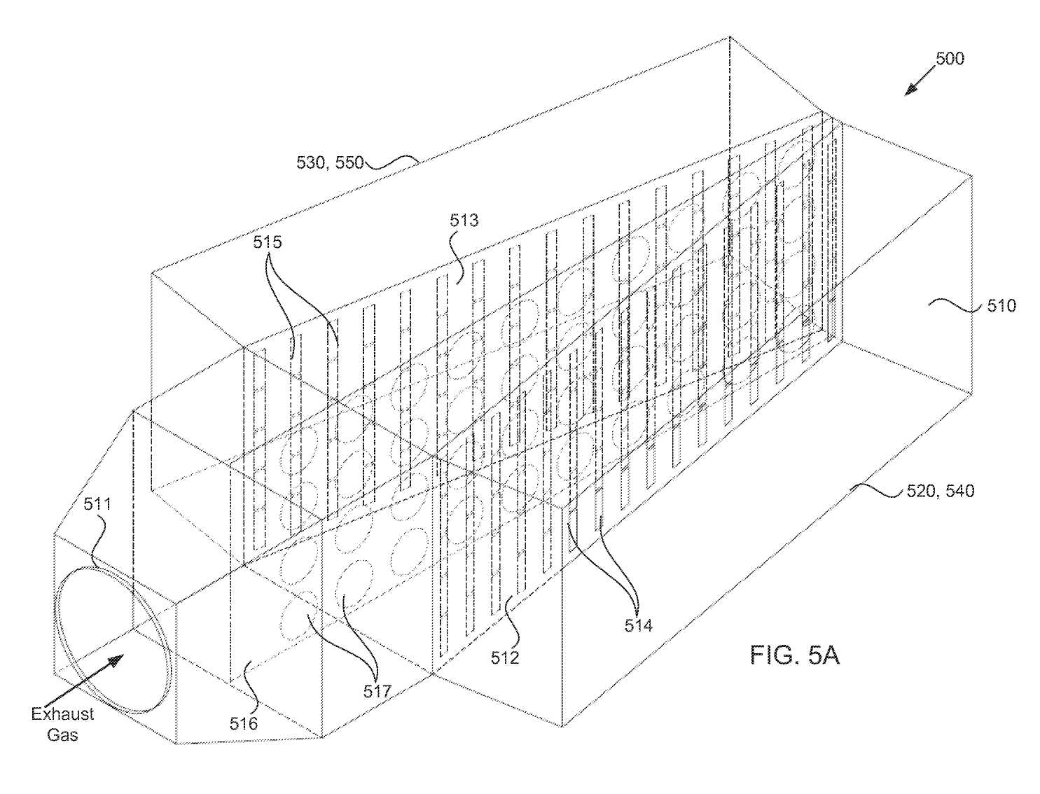

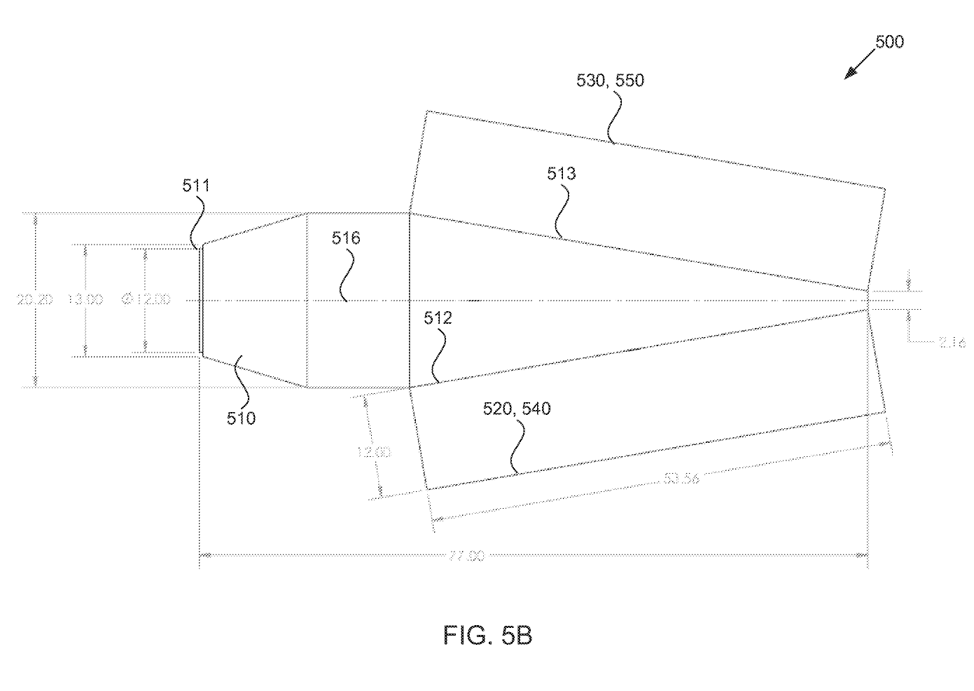

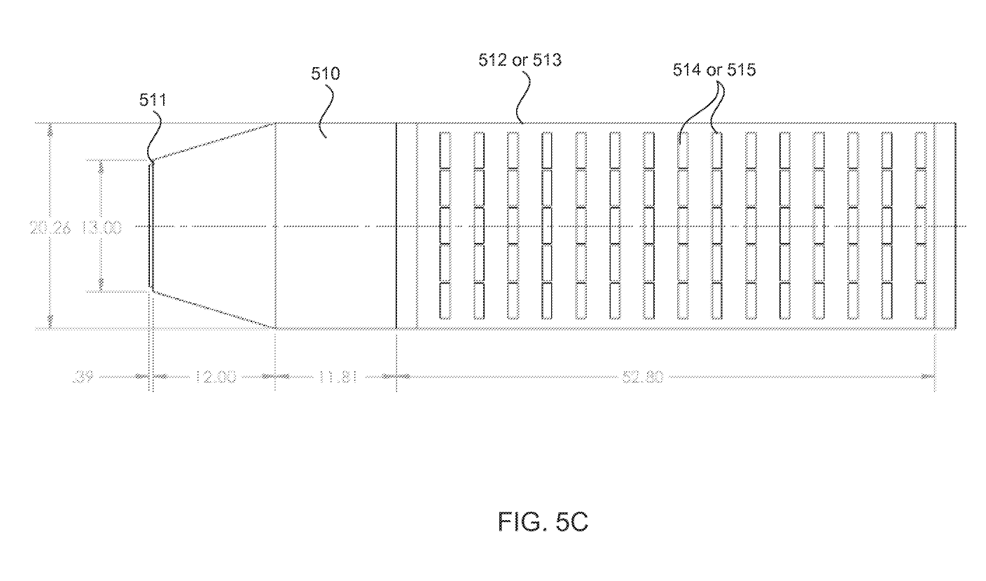

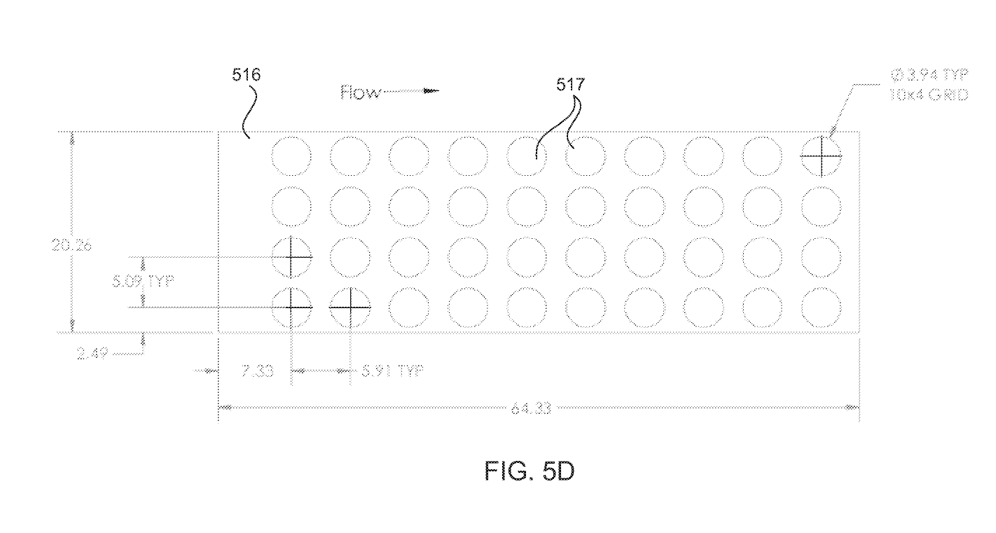

FIGS. 3A-3B schematically illustrate views of exemplary components of a thermoelectric system for use in a thermoelectric generator such as illustrated in FIGS. 1A-1B and 2, according to some embodiments. In one non-limiting embodiment, thermoelectric system 310 corresponds to thermoelectric system 510 described herein with reference to FIGS. 5A-5D, to thermoelectric system 110 described herein with reference to FIGS. 1A-1B, or to thermoelectric system 210 described herein with reference to FIG. 2 Thermoelectric system 300 includes tapered inlet manifold 310 configured to be coupled to an exhaust gas source, e.g., via input port 311 and input piping such as described above with reference to FIGS. 1A-1B and 2. In some embodiments, tapered inlet manifold 310 can be configured analogously as tapered inlet manifold 510 described in greater detail herein with reference to FIGS. 5A-5D. In one non-limiting example, tapered inlet manifold 310 receives hot exhaust from a genset engine through an 8-inch diameter or 12-inch diameter inlet.

In the embodiment illustrated in FIGS. 3A-3B, tapered inlet manifold 310 includes first side 312 defining a first outer surface of the tapered inlet manifold; and second side 313 defining a second outer surface of the tapered inlet manifold (chevron inlet). In some embodiments, first side 312 and second side 313 can be arranged non-parallel to one another. For example, in some embodiments, first side 312 and second side 313 of tapered inlet manifold 310 can be arranged at an angle of between about 5 and 15 degrees relative to one another, e.g., at an angle of about 6-10 degrees relative to one another, e.g., at an angle of about 6.6 degrees.

In the embodiment illustrated in FIGS. 3A-3B, thermoelectric system 300 also includes first plurality of outlet manifolds 320 and second plurality of outlet manifolds 330. Outlet manifolds 320, 330 can be coupled to outlet piping configured to output the fluid after waste heat is extracted therefrom, e.g., such as described above with reference to FIGS. 1A-1B and 2. Thermoelectric system 300 also can include a plurality of thermoelectric generating units (TEG generating units) 340, 350. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. In the embodiment illustrated in FIGS. 3A-3B, first subset 340 of the thermoelectric generating units are coupled to first side 312 of tapered inlet manifold 310 such that the inlet of the hot-side heat exchanger of each thermoelectric generating unit of first subset 340 receives exhaust gas from first side 312 of tapered inlet manifold 310 and the outlet of that hot-side heat exchanger is coupled to an outlet manifold of first plurality of outlet manifolds 320. Additionally, in the embodiment illustrated in FIGS. 3A-3B, second subset 350 of the thermoelectric generating units can be coupled to second side 303 of tapered inlet manifold 310 such that the hot-side heat exchanger of each thermoelectric generating unit of second subset 350 receives exhaust gas from second side 313 of tapered inlet manifold 310 and the outlet of that hot-side heat exchanger is coupled to an outlet manifold of second plurality of outlet manifolds 330. The thermoelectric devices of the plurality of thermoelectric generating units 340, 350 can generate electricity responsive to a temperature differential between the exhaust gas and the first cold-side heat exchangers. Optionally, the cold-side heat exchangers can be liquid-cooled. Substantially uniform flow conditions can be provided across the inlets to both banks of thermoelectric devices (elements). The flow can split to flow through the heat exchangers on each side of the tapered inlet manifold (chevron inlet).

Any suitable number of thermoelectric devices can be included in thermoelectric system 300. For example, thermoelectric system 300 can include a sufficient number of the thermoelectric generating units to generate at least about 5 kW of electricity based on the exhaust gas having a temperature between 400° C.-600° C. and a mass flow of the exhaust gas of between 500-1500 g/s. Illustratively, each of the first and second subsets of thermoelectric generating units 340 independently can include two or more, four or more, eight or more, sixteen or more, thirty-two or more, or sixty-four or more thermoelectric generating units. Additionally, any suitable number of the outlets of the hot-side heat exchangers of the thermoelectric generating units of the first subset 340 or second subset 350 respectively can be coupled to any suitable number of the outlet manifolds. For example, a plurality of the outlets of the hot-side heat exchangers of the thermoelectric generating units of the first subset 340 can be coupled to one outlet manifold of the first plurality of outlet manifolds 320; and a plurality of the outlets of the hot-side heat exchangers of the thermoelectric generating units of the second subset 350 can be coupled to one outlet manifold of the second plurality of outlet manifolds. Such an embodiment can facilitate gas-tight sealing of the outlets of the hot-side heat exchangers to the respective outlet manifold and also can facilitate service and replacement of the thermoelectric generating units. For example, as parts including different materials expand responsive to being exposed to a heated fluid, differences in the thermal expansion coefficients of those materials can result in thermal expansion mismatch, e.g., one part expanding more than another part, potentially reducing a seal between the two parts. The amount of thermal expansion mismatch increases as a function of the size of the parts, e.g., as a function of at least one dimension, or “characteristic length,” of the parts. Accordingly, reducing the relative size of the parts, e.g., by providing a plurality of relatively small outlet manifolds to which a relatively low number of thermoelectric generating units can be coupled, can provide enhanced sealing as compared to a single relatively large outlet manifold to which a relatively high number of thermoelectric generating units are coupled. Additionally, providing a plurality of relatively small outlet manifolds to which a relatively low number of thermoelectric generating units can be coupled can simplify service or replacement of the thermoelectric generating units, e.g., by impacting at most the thermoelectric generating units that are coupled to a single one of the outlet manifolds (e.g., causing that relatively low number of thermoelectric generating units to need to be detached from the outlet manifold to service so as to service or replace one of the thermoelectric generating units). In comparison, for a single relatively large outlet manifold to which a relatively high number of thermoelectric generating units are coupled, and in which each of those thermoelectric generating units potentially may be impacted if a single one of those thermoelectric generating units needs to be serviced or replaced (e.g., causing that relatively high number of thermoelectric generating units to need to be detached from the outlet manifold to service so as to service or replace one of the thermoelectric generating units). As one non-limiting example, four of the outlets of the hot-side heat exchangers of the thermoelectric generating units of the first subset 340 can be coupled to one outlet manifold of the first plurality of outlet manifolds; and four of the outlets of the hot-side heat exchangers of the thermoelectric generating units of the second subset 350 can be coupled to one outlet manifold of the second plurality of outlet manifolds. As illustrated in FIG. 3B, one or more turning vanes or perforated plates 360 can be provided so as to provide flow control. Additionally, thermoelectric system 300 can include housing 301, e.g., a box. In one non-limiting example, the housing is approximately 5 feet in length, 4 feet wide, and 2 feet tall.

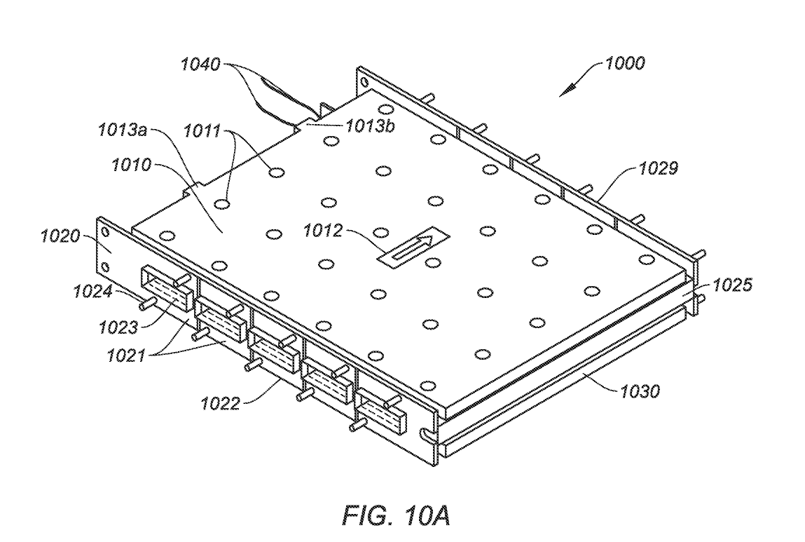

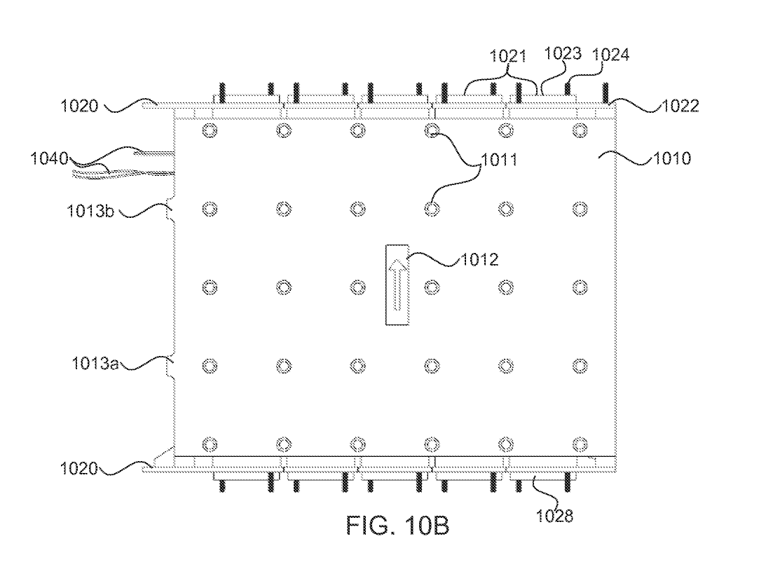

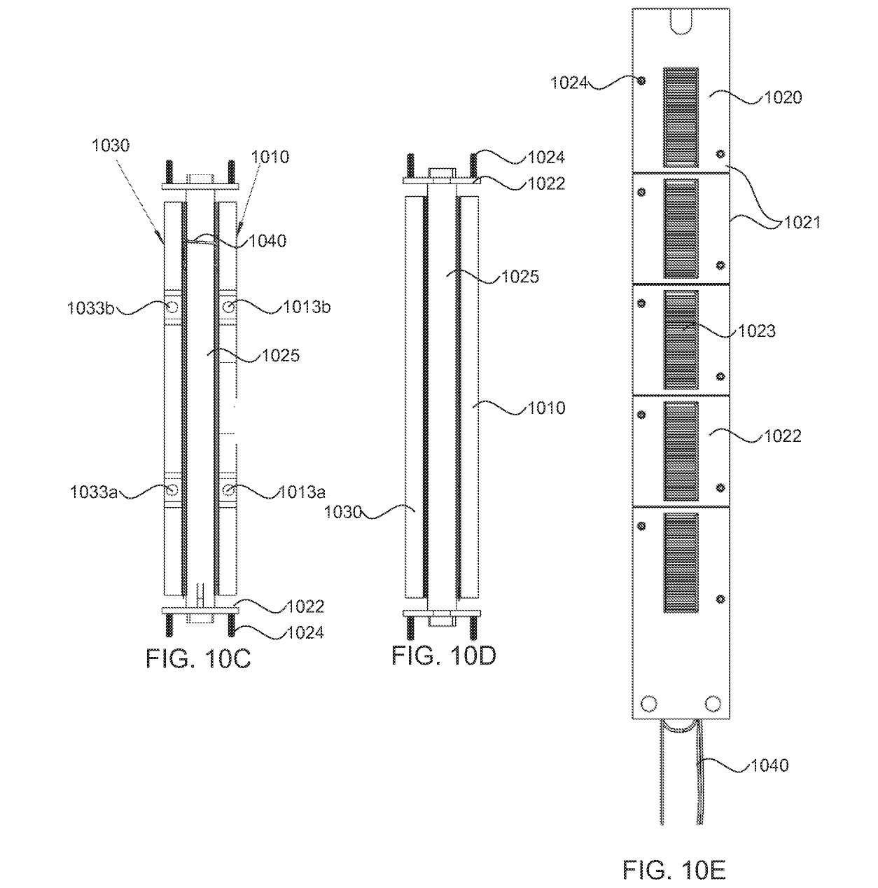

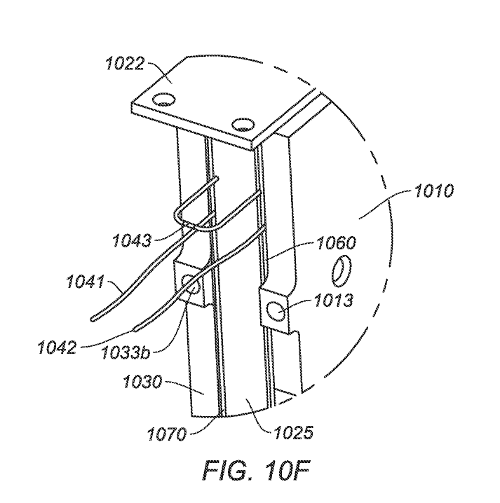

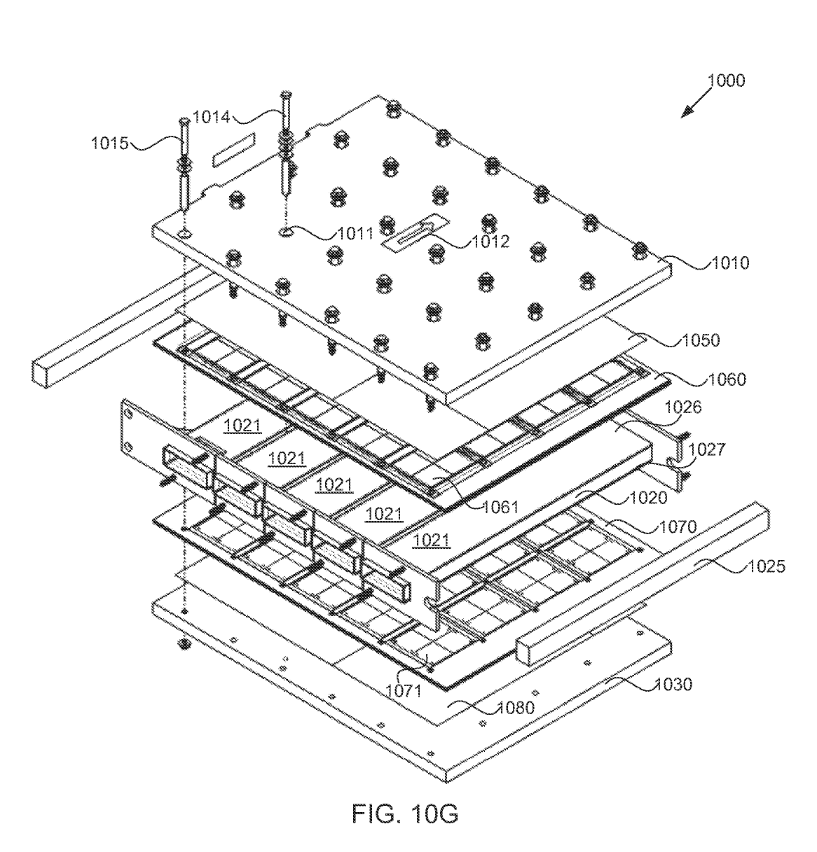

The thermoelectric generating units 340, 350 can have any suitable configuration. In one nonlimiting embodiment, the present thermoelectric generators (TEG) such as described herein with reference to FIGS. 1A-1B, 2, and 3A-3B include a TEG generating unit or thermoelectric generating unit (TGU) such as described in the above-mentioned U.S. Provisional Patent Application No. 62/059,084, filed on Oct. 2, 2014, and in U.S. patent application No. (TBA), filed on even date herewith and entitled “THERMOELECTRIC GENERATING UNIT AND METHODS OF MAKING AND USING THE SAME,” and as described in greater detail below with reference to FIGS. 10A-16. But it should be understood that the present TEG suitably can be used independently of such a TGU, e.g., can be used with a differently configured TGU, or with another type of thermoelectric device that can convert waste heat into electricity.

In some embodiments, TEG system gross and net power can be greater than about 5 kW, based on hot inlet temperatures between 400° C.-600° C. and mass flows between 500-1500 g/s. Illustratively, but not necessarily, the physical size of the TEG system can be greater than 5 ft×5 ft×5 ft (125 ft³) and >1000 lbs. It should be appreciated that other dimensions and characteristics suitably can be used. In some embodiments, the TEG system can be configured as a containerized system or turnkey TEG on a skid that can be transported as one unit, e.g., such as described above with reference to FIGS. 1A-1B.

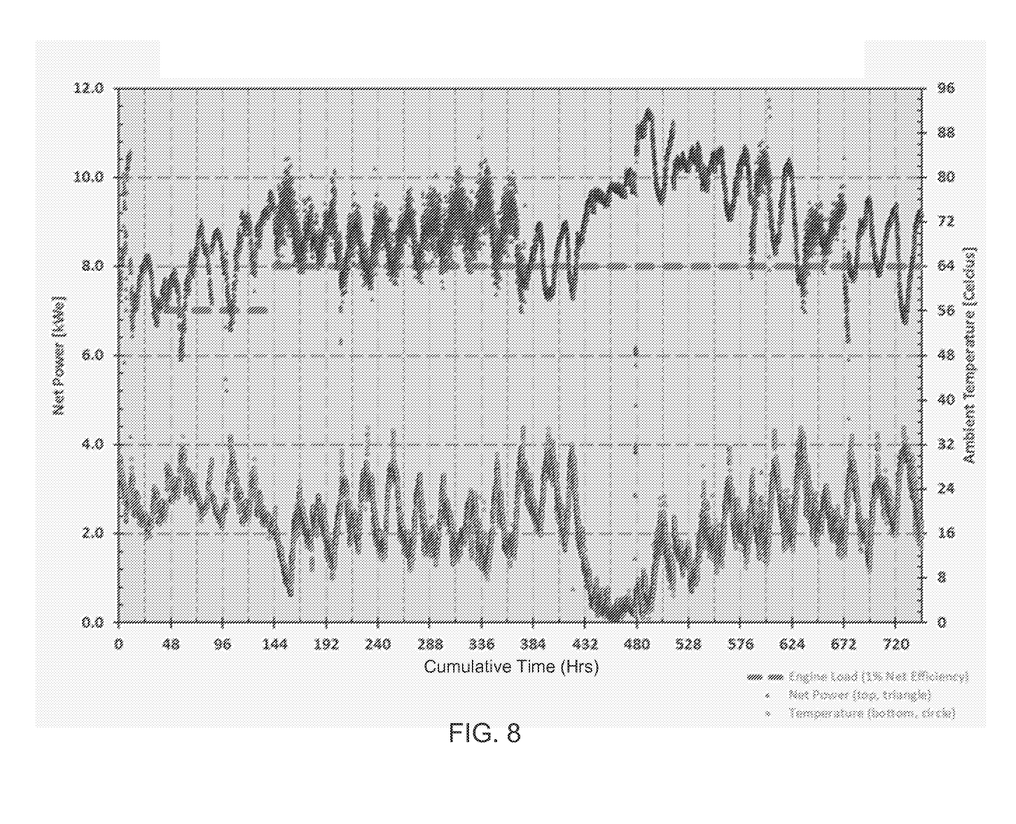

An exemplary TEG (e.g., generator 100 illustrated in FIGS. 1A-1B or generator 200 illustrated in FIG. 2, optionally including thermoelectric system 300 illustrated in FIGS. 3A-3B) prepared as provided herein was operated for over 30 days producing between 8-12 kW of net power, maintaining >1% net efficiency improvement. FIG. 8 illustrates a plot of exemplary test results from such an exemplary TEG system. FIG. 8 also shows an exemplary, nonlimiting manner in which the TEG system performance can vary as a function of ambient temperature. More specifically, FIG. 8 illustrates a plot of measured net power as a function of time for a thermoelectric generator such as illustrated in FIGS. 1A-1B and 2, according to some embodiments. As can be seen in FIG. 8, the measured net power (left y-axis) oscillates as a function of time, with such oscillations corresponding to increases and decreases in the ambient temperature (right y-axis) over the course of the day. Based on FIG. 8, it also can be understood how the measured net power increases when the load on the engine supplying the hot exhaust increases, seen especially around t=144 hours.

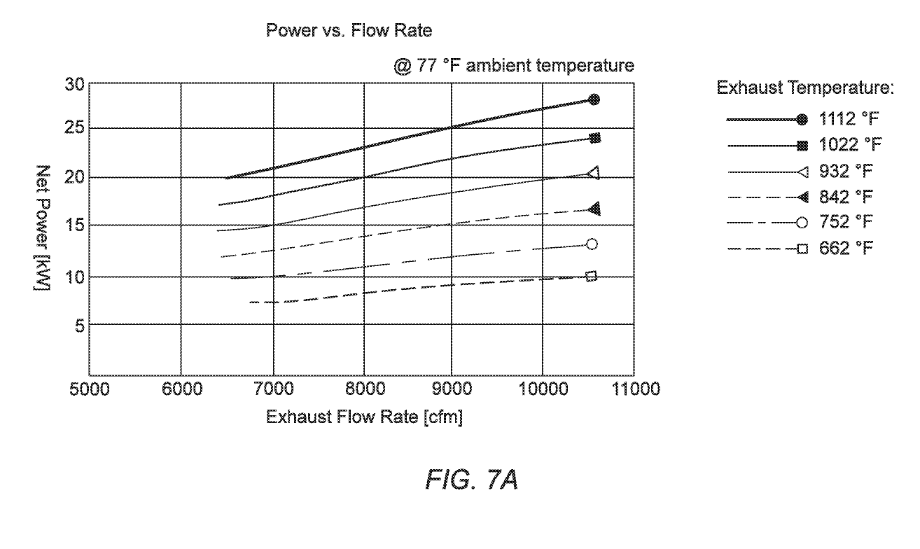

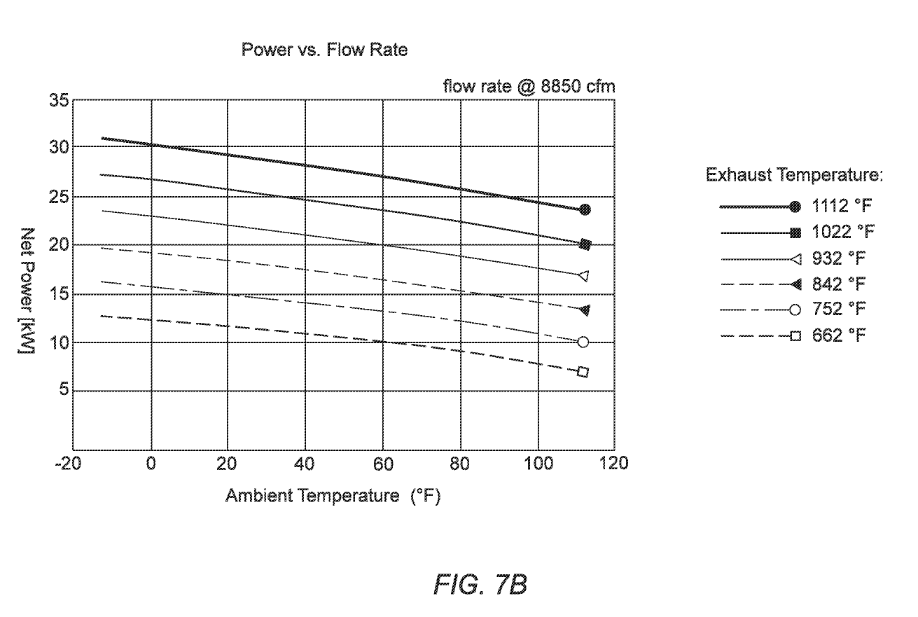

FIG. 7A illustrates a plot of exemplary power as a function of exhaust flow rate and inlet temperature through a thermoelectric generator such as illustrated in FIGS. 1A-1B and 2, according to some embodiments. From FIG. 7A, it can be understood that the net power produced by the thermoelectric generator increases as a function of exhaust flow rate. From FIG. 7A, it also can be understood that the net power produced by the thermoelectric generator increases as a function of exhaust inlet temperature. FIG. 7B illustrates a plot of exemplary power as a function of ambient and exhaust inlet temperature for a thermoelectric generator such as illustrated in FIGS. 1A-1B and 2, according to some embodiments. From FIG. 7B, it can be understood that the net power produced by the thermoelectric generator decreases as a function of ambient temperature. From FIG. 7B, it also can be understood that the net power produced by the thermoelectric generator increases as a function of exhaust inlet temperature.

In some embodiments, the TEG system (e.g., generator 100 illustrated in FIGS. 1A-1B or generator 200 illustrated in FIG. 2, optionally including thermoelectric system 300 illustrated in FIGS. 3A-3B) includes 32 rectangular TEG generating units or modules with a cross sectional area of 1.5 m², although it should be appreciated that other cross-sectional areas suitably can be used. In some embodiments, the exhaust pipe(s) of the engine have cross sectional areas in the range of about 0.1 m², although it should be appreciated that other cross-sectional areas suitably can be used. In some embodiments, there is an order of magnitude increase in cross sectional area as the flow transitions from the exhaust pipe(s) to the TEG. In some embodiments, the exhaust gases are distributed, e.g., partially, substantially, or completely evenly distributed, to different thermoelectric modules so as suitably to extract energy while reducing or inhibiting pressure losses. Some embodiments provide a relatively compact transition configuration that can interface the exhaust pipe(s) of the engine to the TEG. In some embodiments, the configuration provides a relatively uniform flow distribution in the TEG generating units or thermoelectric modules. As noted above, FIG. 3B illustrates one exemplary layout that can be used in a TEG, according to some embodiments. As noted above, FIG. 3A illustrates another exemplary diagram that can be used in a TEG, according to some embodiments. FIG. 3A illustrates exemplary inlet and outlet transitions as well as an exemplary manner in which each outlet transition can be connected to a plurality of individual TEG generating units or modules, e.g., to two, three, four, five, six, seven, eight, nine, ten, or more than ten individual TEG generating units or modules. In the exemplary embodiment illustrated in FIG. 3A, the inlet transition includes a tapered shape so as to facilitate balancing the flow distribution through each TEG generating unit. It should be appreciated that inlet transitions having other shapes suitably can be used.

Additionally, or alternatively, in some embodiments, the TEG system (e.g., generator 100 illustrated in FIGS. 1A-1B or generator 200 illustrated in FIG. 2, optionally including thermoelectric system 300 illustrated in FIGS. 3A-3B) includes an Uninterruptable Power Supply (UPS) connected to the coolant system. In some embodiments, the UPS can provide power for a brief period of time (e.g., for about 20-30 minutes) in the event of unexpected grid power loss. In some embodiments, the UPS power can be provided to either the coolant pump only, or to the fan, or to the coolant pump and fan.

Additionally, or alternatively, in some embodiments, the TEG (e.g., generator 100 illustrated in FIGS. 1A-1B or generator 200 illustrated in FIG. 2, optionally including thermoelectric system 300 illustrated in FIGS. 3A-3B) is cooled so as to inhibit overheating of the cold side (cold-side heat exchangers) of the TEG. In some embodiments, the coolant itself is maintained at a temperature below the boiling point of the coolant (e.g., below about 120° C. for an exemplary coolant including 50%/50% ethylene glycol/water). In addition, or alternatively, in some embodiments, the cold junction between the TE material and the shunt (material electrically coupling together thermoelectric devices of a TEG generating unit or module) can be maintained at a temperature below the melting temperature of the joining material of the junction, e.g., solder (which has an exemplary melting temperature of approximately 220° C.). In some embodiments, other materials in the TEG also can have temperature limitations (in one nonlimiting example, a polyimide substrate, or the like). In some embodiments, providing power to run the coolant pump may be sufficient to keep the TEG cool enough without necessarily running the coolant fan, and thus potentially can extend the run time of the UPS. An exemplary cooling system 230 is described herein with reference to FIG. 2.

Additionally, or alternatively, in some embodiments, a diverter valve can be engaged so as to divert the flow of exhaust gas from the TEG (e.g., generator 100 illustrated in FIGS. 1A-1B or generator 200 illustrated in FIG. 2, optionally including thermoelectric system 300 illustrated in FIGS. 3A-3B) in the event of power loss to the coolant system, e.g., such as the diverter valve described above with reference to FIGS. 1A-1B or diverter valve 261 described above with reference to FIG. 2.

In addition to using a UPS system in the event of a power loss, or as an alternative to the UPS system, the power output of the TEG (e.g., generator 100 illustrated in FIGS. 1A-1B or generator 200 illustrated in FIG. 2, optionally including thermoelectric system 300 illustrated in FIGS. 3A-3B) can be used to power the coolant system (e.g., cooling system 230 illustrated in FIG. 2) until sufficient heat has been removed so as to maintain the TEG below any cold side limitations, e.g., so as to reduce the likelihood of damage to the thermoelectric material. For example, in some embodiments, TEG power can be provided, e.g., through an inverter (e.g., one or more power inverters 251 illustrated in FIG. 2), so as to power the coolant system, or can be supplied directly if a DC powered coolant system is used. In some embodiments, e.g., in a UPS or direct TEG power based embodiment, the coolant system (e.g., cooling system 230 illustrated in FIG. 2) can be wired in parallel between the grid and the other power source. In some embodiments, if one or more power sources are lost, one or more other power sources can be available. Alternative wiring schemes, e.g., known wiring schemes, can also be used.

Additionally, or alternatively, in some embodiments, the TEG (e.g., generator 100 illustrated in FIGS. 1A-1B or generator 200 illustrated in FIG. 2, optionally including thermoelectric system 300 illustrated in FIGS. 3A-3B) can include access ports in the inlet and/or outlet transition so as to facilitate cleaning of the heat exchangers (e.g., hot-side heat exchangers such as described herein with reference to FIGS. 1A-1B, 2, 3A-3B, and 5A-5D). In one nonlimiting example, air or steam jets can be inserted through such access ports so as to partially, substantially, or completely clean the heat exchangers of any accumulated soot and debris. Additionally, or alternatively, in some embodiments, fuel can be injected through such access ports so as to facilitate targeted combustion so as to create a regeneration process for heat exchanger fouling.

Additionally, or alternatively, in some embodiments, exhaust sealing can be provided, and/or the accommodation of thermal expansion differences for heat transfer components that are installed in a waste heat stream and actively cooled can be provided. In some embodiments, an exemplary configuration approach includes bolting components to a duct, e.g., using Belleville or spring washers so as to inhibit bolt loosening. Additionally, or alternatively, in some embodiments, a sandwich intumescent gasket can be provided so as to partially, substantially, or completely seal relatively large gaps. Additionally, or alternatively, in some embodiments, bellows on the inlet of the exhaust duct can be provided so as to facilitate thermal expansion of the components. Additionally, or alternatively, in some embodiments, heat exchanger tubes can be protruded into holes in the mounting plate so as to provide a relatively tortuous path for exhaust. Additionally, or alternatively, in some embodiments, mounting of individual heat exchangers can facilitate a reduction of any impact of differences in thermal expansion of such components.

Additionally, or alternatively, loss of thermal energy can be reduced and internal components of the TEG (e.g., generator 100 illustrated in FIGS. 1A-1B or generator 200 illustrated in FIG. 2, optionally including thermoelectric system 300 illustrated in FIGS. 3A-3B) can be maintained at a relatively cool temperature. For example, in some embodiments, the exhaust duct can be insulated, e.g., with blanket insulation, e.g., with internal and/or external insulation. In some embodiments, internal insulation can include cladding, e.g., including separate plates that are mounted to the external shell. In some embodiments, insulation is sandwiched between the cladding and shell. In some embodiments, the use of such separate plates can facilitate thermal expansion and/or can inhibit warping of the plates.

Additionally, or alternatively, and as discussed above with reference to FIGS. 1A-1B and 2, exhaust gas can be directed around (e.g., can by-pass) the TEG without necessarily shutting down the engine (or process) to which the TEG is connected, e.g., using diverter valve 261. Exemplary reasons for by-passing the TEG can include the TEG being temporarily unusable because of equipment issue or because of power loss, or because operating the TEG at a particular time can require more energy than the TEG produces. In some embodiments, the diverter or by-pass system can be controlled by the TEG control system, and illustratively can include feedback on diverter or by-pass valve position using limit switches provided in the valve or in an actuator for such valve. In some embodiments, if power to the TEG is lost or it otherwise is useful to by-pass the TEG, the diverter or by-pass system illustratively can bypass the TEG through a spring return mechanism. In some embodiments, the diverter or by-pass system can include a single 3-way valve or two separate valves, although other valve configurations suitably can be used.

Additionally, or alternatively, the TEG system (e.g., generator 100 illustrated in FIGS. 1A-1B or generator 200 illustrated in FIG. 2, optionally including thermoelectric system 300 illustrated in FIGS. 3A-3B) can be configured so as to be at least partially modular. For example, in some embodiments, different combinations of TEG generating units can be connected to the inlet and outlet transitions, e.g., so as to enhance power output while maintaining acceptable exhaust backpressure on the upstream engine. In some embodiments, the TEG system can be configured so that the engine to which the TEG system is coupled need not be overhauled or significantly modified, but in some embodiments may be coupled to the TEG via a connection to the exhaust stream, e.g., via input piping described herein with reference to FIGS. 1A-1B and 2, thus facilitating a reduction or elimination of engine shutdown time. In some embodiments, TEG modules can be individually connected to the exhaust and coolant supplies and sinks, meaning that the TEG modules can be removed and/or replaced without necessarily affecting other portions of the TEG system. Additionally, or alternatively, in some embodiments, arrangement of the TEG modules relative to the coolant and exhaust manifolds can facilitate an individual to slide the TEG modules in or out without necessarily requiring the individual to utilize mechanical lifting equipment (e.g., cranes, hoists, forklifts, or the like). Additionally, or alternatively, in some embodiments, use of locking quick disconnects on the coolant hoses can facilitate removal of TEG modules without necessarily draining the coolant system, and also can facilitate the “hot” disconnection of TEG modules, for example, in case of a hose rupture or module leak.

Additionally, or alternatively, in some embodiments, the circuits in the TEG modules can be configured such that, in a wide range of operating conditions, the circuits can function with commercially available inverters, e.g., one or more power inverters 251 such as illustrated in FIG. 2, e.g., off-the-shelf solar inverters. In some embodiments, such a use of an inverter can facilitate the integration of a varying DC power source—e.g., in some embodiments, the TEG—into a standard AC grid. In some embodiments, the configuration of the TEG circuitry can facilitate both device-level and module-level redundancy. For example, in some embodiments, some or all of the TE devices within a TEG module can be wired in a series-parallel arrangement with one another such that a single TE device failure does not necessarily significantly reduce the power output of the TEG module. Additionally, or alternatively, in some embodiments, some or all of the TEG modules within the TEG can be electrically connected in parallel with one another so that failure of a single TEG module need not affect the remaining TEG modules' ability to produce power. In some embodiments, TEG modules can be configured so as to meet or exceed the safety requirements of the inverter, e.g., of the solar inverter, such that the TEG modules pass certification and work with the safety features of the inverter.

Additionally, or alternatively, in some embodiments, the TEG (e.g., generator 100 illustrated in FIGS. 1A-1B or generator 200 illustrated in FIG. 2, optionally including thermoelectric system 300 illustrated in FIGS. 3A-3B) can be configured so as to operate “off-grid,” e.g., without the need to be connected to an existing AC electrical grid. Such an off-grid configuration can produce AC power from the thermoelectric devices of the thermoelectric system, without requiring a primary AC electrical grid to be present. This is particularly useful as so many consumer and industrial products use AC electricity and therefore require AC generating capacity to operate. Such a feature can facilitate use of the present TEG in many markets that currently do not have access to electricity or obtain it at great cost.

For example, the TEG (e.g., generator 100 illustrated in FIGS. 1A-1B or generator 200 illustrated in FIG. 2, optionally including thermoelectric system 300 illustrated in FIGS. 3A-3B) can be modified so as to include a combination of components, e.g., commercially available off-the-shelf products from the solar industry, so as to convert the DC electricity generated by the TEG modules into AC electricity. Such additional components can be configured so as to “create” an AC grid (nominally 50 or 60 Hz), which can be used to establish an AC system. Excess energy can be stored in batteries, which can facilitate grid stability as well as continued power delivery to the customer even when waste heat is not available. The TEG also can include a control system (e.g., including both hardware and software components) configured to provide energy to the customer for as long practicable without production from the TEG modules while still maintaining battery capacity to restart and run auxiliary systems. Such a control system suitably can include a combination of relays, contactors, and inverters, working together to turn the customer connection on and off when appropriate.

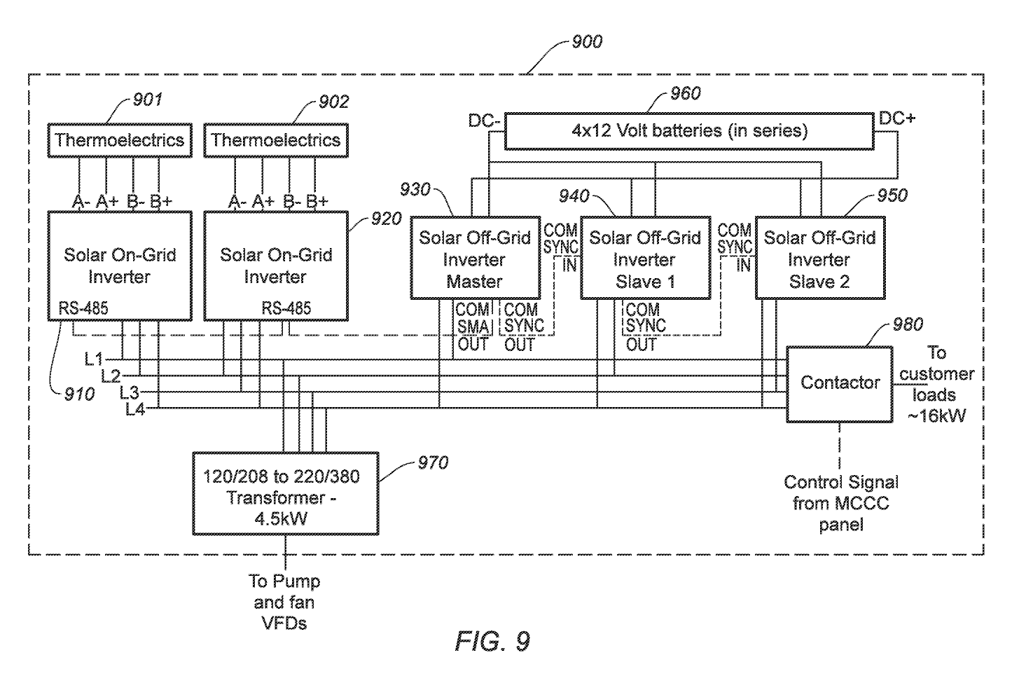

For example, FIG. 9 illustrates an exemplary inverter system for use with a thermoelectric generator such as illustrated in FIGS. 1A-1B and 2, according to some embodiments. Inverter system 900 illustrated in FIG. 9 can be configured to be coupled to a first plurality of thermoelectric devices 901 (which can correspond to the first plurality of thermoelectric devices described herein with reference to FIG. 1A-1B, 2, 3A-3B, or 5A-5D) and to a second plurality of thermoelectric devices 902 (which can correspond to the second plurality of thermoelectric devices described herein with reference to FIG. 1A-1B, 2, 3A-3B, or 5A-5D). For example, inverter system 900 can include first solar on-grid inverter 910 coupled to first plurality of thermoelectric devices 901 via standard electrical wires, labeled with “A” and “B” as well as “+” and “−” to indicate sub-groupings of the thermoelectric devices and polarity, and second solar on-grid inverter 910 coupled to second plurality of thermoelectric devices 902 via standard electrical wires, labeled with “A” and “B” as well as “+” and “−” to indicate sub-groupings of the thermoelectric devices and polarity. First and second solar on-grid inverters 910, 920 can include any suitable on-grid inverter, e.g., a Sunny Boy 7700TL-US on-grid inverter such as commercially available from SMA Solar Technology AG (Niestetal, Germany).

Inverter system 900 further can include first solar off-grid inverter 930, second solar off-grid inverter 940, third solar off-grid inverter 950, batteries 960, transformer 970, and contactor 980. First, second, and third solar off-grid inverters 930, 940, 950 can include any suitable off-grid inverter, e.g., a Sunny Island 6048 US off-grid inverter such as commercially available from SMA Solar Technology AG (Niestetal, Germany). In one non-limiting embodiment, first solar off-grid inverter 930 can be configured as a master inverter, second solar off-grid inverter 940 can be configured as a first slave inverter, and third solar off-grid inverter 950 can be configured as a second slave inverter. Batteries 960 can include any suitable number, type, and arrangement of batteries configured so as to store DC energy produced by thermoelectric devices 940, 950 for use in powering one or both of a customer load and internal components of the TEG. Transformer 970 can be configured to transform the voltage produced by 910, 920, 930, 940, and 950 into voltage used by the pump and fan VFDs. Contactor 980 can be configured to permit automated connection to and disconnection from customer load. This allows the TEG to safely shut down, e.g., under a circumstance in which the supply of waste heat is insufficient (e.g., the engine goes to idle or shuts down) but the customer's load is still drawing power, which would typically drain down the batteries. If the batteries were to fully drain, the pump and fans may not be able to operate, thus presenting a risk of overheating (e.g., even if the engine is off, as residual heat in the modules could still be enough to damage the thermoelectrics). Additionally, if the batteries were to be fully drained, the TEG may not be able to start up when the exhaust supply comes back up. Contactor 980 therefore provides a safeguard and can facilitate continued operation of the unit without user intervention.

In the non-limiting embodiment illustrated in FIG. 9, first solar on-grid inverter 910, transformer 970, first solar off-grid inverter 930, and contactor 980 are in electrical contact with one another via first wiring L1. Additionally, first solar on-grid inverter 910, second solar on-grid inverter 920, transformer 970, second solar off-grid inverter 940, and contactor 980 are in electrical contact with one another via second wiring L2. Additionally, second on-grid solar inverter 920, transformer 970, third off-grid solar inverter 950, and contactor 980 are in electrical contact with one another via third wiring L3. Additionally, first solar on-grid inverter 910, second solar on-grid inverter 920, transformer 970, first solar off-grid inverter 930, second solar off-grid inverter 940, third solar off-grid inverter 950, and contactor 980 each are connected to one another via neutral wiring N. Additionally, first solar on-grid inverter and second solar on-grid inverter 920 are in electrical contact with one another via an RS-485 communication line. Additionally, second solar on-grid inverter 920 and first solar off-grid inverter 930 are in electrical contact with one another via an RS-485 communication line. Additionally, first solar off-grid inverter 930 and second solar off-grid inverter 940 are in electrical contact with one another via a COM SYNC OUT communication line. Additionally, second solar off-grid inverter 940 and third solar off-grid inverter 950 are in electrical contact with one another via a COM SYNC OUT communication line. Additionally, first, second, and third solar off-grid inverters 930, 940, 950 are in electrical contact with batteries 960 via DC+ wiring and DC-wiring. Additionally, transformer 970 is in electrical communication with the cooling system, e.g., pump and fan VFDs (Variable Frequency Drives). Additionally, contactor 980 is in electrical contact with customer loads and with a controller, e.g., PLC system 254 described herein with reference to FIG. 2, e.g., which can be included in an MCCC (Module Cascading Connection Circuit) panel.

During use, first plurality of thermoelectric devices 901 and second plurality of thermoelectric devices 902 produce DC electricity, which is inverted into AC electricity by first solar on-grid inverter 910 and second solar on-grid inverter 920, respectively. This AC electricity is connected to the main electrical bus (e.g., distribution panel board 252 illustrated in FIG. 2), which is used to power the TEG's loads (pump and fans for cooling, PLC for controls (e.g., PLC system 254 illustrated in FIG. 2), modem for wireless communication, and other miscellaneous loads), keep batteries 960 charged, and power the customer load (e.g., site electrical system 260 illustrated in FIG. 2). In the embodiment illustrated in FIG. 9, first solar off-grid inverter 930, second solar off-grid inverter 940, and third solar off-grid inverter 950 can serve several purposes: first, off-grid inverters 930, 940, 950 can invert DC electricity from batteries 960 into AC electricity, delivering it to the main electrical bus; second, off-grid inverters 930, 940, 950 can rectify AC electricity from the main electrical bus to DC electricity, delivering it to batteries 960; third, off-grid inverters 930, 940, 950 can “create” an AC electrical grid, forming the 50 to 60 Hz frequency that may be required by first solar on-grid inverter 910 and second solar on-grid inverter 920 before inverters 910, 920 can deliver AC electricity to the main electrical bus. First solar off-grid inverter 930 also communicates with first solar on-grid inverter 910 and second solar on-grid inverter 920 to let on-grid inverters 910, 920 know when on-grid inverters 910, 920 need to supply less power, either because batteries 960 are fully charged, there isn't enough load, or both.

Note that the non-limiting embodiment illustrated in FIG. 9 can represent an “off-grid” version, where there is no AC grid provided on the customer's side (just loads). In this case, batteries 960 can be used to start up the TEG and to help off-grid solar inverters 930, 940, and 950 “create” the AC grid. Solar on-grid inverters 910, 920 and solar off-grid inverters 930, 940, and 950 optionally can be combined into a single inverter unit, as some new products do (e.g., as available from Schneider Electric, for example). In alternative embodiments, e.g., an “on-grid” version of a similar system, off-grid inverters 930, 940, 950, and batteries 960 may not necessarily be required, and can be omitted; in some such embodiments, start-up power and AC grid creation can be supplied externally by a local or regional AC electric grid.

Additionally, or alternatively, in some embodiments, the introduction of an exhaust heat recovery unit, such as the present TEG, also can reduce exhaust noise so as to reduce or eliminate the need for a silencer on the engine. For example, the TEG can provide a suitable combination of back pressure, change of flow velocity, and complex internal structure (fins) so as suitably to extract waste heat from the engine exhaust and also can provide a similar or same effect as a silencer. Such an effect has been demonstrated on a full scale trial for a 10 dB reduction on an 800 kW engine and 22 dB on a 30 kW engine. In some embodiments, the use of thermoelectric materials allow the creation of a silencer that generates power.

Additionally, or alternatively, the TEG system includes an overvoltage protection circuit so as to facilitate the production of power at voltages within required regulations and to inhibit damage to an inverter, if provided, and/or to other parts of the system.

FIGS. 5A-5D schematically illustrate views of exemplary components of a thermoelectric system for use in a thermoelectric generator such as illustrated in FIGS. 1A-1B and 2, according to some embodiments. In one non-limiting embodiment, thermoelectric system 510 corresponds to thermoelectric system 310 described herein with reference to FIGS. 3A-3B, to thermoelectric system 110 described herein with reference to FIGS. 1A-1B, or to thermoelectric system 210 described herein with reference to FIG. 2. The exemplary dimensions shown in FIGS. 5B-5D are intended to be purely illustrative, and not limiting in any way. Any other suitable dimensions can be used.

Thermoelectric system 500 includes tapered inlet manifold 510 configured to be coupled to an exhaust gas source, e.g., via input port 511 and input piping such as described above with reference to FIGS. 1A-1B and 2. In some embodiments, tapered inlet manifold 510 can be configured analogously as tapered inlet manifold 310 described in greater detail herein with reference to FIGS. 3A-3B. In one non-limiting example, tapered inlet manifold 510 receives hot exhaust from a genset engine through an 8-inch diameter or 12-inch diameter inlet.

In the embodiment illustrated in FIGS. 5A-5D, tapered inlet manifold 510 includes first side 512 defining a first outer surface of the tapered inlet manifold; and second side 513 defining a second outer surface of the tapered inlet manifold (chevron inlet). In some embodiments, first side 512 and second side 513 can be arranged non-parallel to one another. For example, in some embodiments, first side 512 and second side 513 of tapered inlet manifold 510 can be arranged at an angle of between about 5 and 15 degrees relative to one another, e.g., at an angle of about 6-10 degrees relative to one another, e.g., at an angle of about 6.6 degrees. Optionally, first side 512 can include a first plurality of apertures 514 defined therethrough, and second side 513 can include a plurality of apertures 515 defined therethrough. Optionally, the apertures of first plurality of apertures 514 and second plurality of apertures 515 are approximately rectangular.

In the embodiment illustrated in FIGS. 5A-5D, thermoelectric system 500 also includes a first plurality of outlet manifolds 520 and a second plurality of outlet manifolds 530. Outlet manifolds 520, 530 can be coupled to outlet piping configured to output the fluid after waste heat is extracted therefrom, e.g., such as described above with reference to FIGS. 1A-1B and 2. Thermoelectric system 500 also can include a plurality of thermoelectric generating units (TEG generating units) 540, 550. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. In the embodiment illustrated in FIGS. 5A-5D, first subset 540 of the thermoelectric generating units are coupled to first side 512 of tapered inlet manifold 510 such that the inlet of the hot-side heat exchanger of each thermoelectric generating unit of first subset 540 receives exhaust gas from first side 512 of tapered inlet manifold 510, e.g., via apertures 514, and the outlet of that hot-side heat exchanger is coupled to an outlet manifold of first plurality of outlet manifolds 520. Additionally, in the embodiment illustrated in FIGS. 5A-5D, second subset 550 of the thermoelectric generating units can be coupled to second side 503 of tapered inlet manifold 510 such that the hot-side heat exchanger of each thermoelectric generating unit of second subset 550 receives exhaust gas from second side 513 of tapered inlet manifold 510, e.g., via apertures 515, and the outlet of that hot-side heat exchanger is coupled to an outlet manifold of second plurality of outlet manifolds 530. The thermoelectric devices of the plurality of thermoelectric generating units 540, 550 can generate electricity responsive to a temperature differential between the exhaust gas and the first cold-side heat exchangers. Optionally, the cold-side heat exchangers can be liquid-cooled. Substantially uniform flow conditions can be provided across the inlets to both banks of thermoelectric devices (elements).

The flow can split to flow through the heat exchangers on each side of the tapered inlet manifold (chevron inlet). For example, in some embodiments, thermoelectric system 500 optionally can include splitter 516 disposed within tapered outlet manifold 510 and configured to divide the flow of exhaust gas, e.g., approximately evenly, towards first side 512 and towards second side 513. In one non-limiting example, optional splitter 516 is arranged between first side 512 and second side 513 so as approximately to bisect an angle between the first side and the second side. Optional splitter 516 optionally can include a third plurality of apertures 517 so as to facilitate cross-flow of exhaust gas in the space between first side 512 and second side 513.

Any suitable number of thermoelectric devices can be included in thermoelectric system 500. For example, thermoelectric system 500 can include a sufficient number of the thermoelectric generating units to generate at least about 5 kW of electricity based on the exhaust gas having a temperature between 400° C.-600° C. and a mass flow of the exhaust gas of between 500-1500 g/s. Illustratively, each of the first and second subsets of thermoelectric generating units 540 independently can include two or more, four or more, eight or more, sixteen or more, thirty-two or more, or sixty-four or more thermoelectric generating units. Additionally, any suitable number of the outlets of the hot-side heat exchangers of the thermoelectric generating units of the first subset 540 or second subset 550 respectively can be coupled to any suitable number of the outlet manifolds. For example, a plurality of the outlets of the hot-side heat exchangers of the thermoelectric generating units of the first subset 540 can be coupled to one outlet manifold of the first plurality of outlet manifolds 520; and a plurality of the outlets of the hot-side heat exchangers of the thermoelectric generating units of the second subset 550 can be coupled to one outlet manifold of the second plurality of outlet manifolds. As one non-limiting example, four of the outlets of the hot-side heat exchangers of the thermoelectric generating units of the first subset 540 can be coupled to one outlet manifold of the first plurality of outlet manifolds; and four of the outlets of the hot-side heat exchangers of the thermoelectric generating units of the second subset 550 can be coupled to one outlet manifold of the second plurality of outlet manifolds. As illustrated in FIG. 5D, one or more turning vanes or perforated plates 560 can be provided so as to provide flow control. Additionally, thermoelectric system 500 can include housing 501, e.g., a box. In one non-limiting example, the housing is approximately 5 feet in length, 4 feet wide, and 2 feet tall.

The thermoelectric generating units 540, 550 can have any suitable configuration. In one nonlimiting embodiment, the present thermoelectric generators (TEG) such as described herein with reference to FIGS. 1A-1B, 2, and 5A-5D include a TEG generating unit or thermoelectric generating unit (TGU) such as described in the above-mentioned U.S. Provisional Patent Application No. 62/059,084, filed on Oct. 2, 2014, and in U.S. patent application No. (TBA), filed on even date herewith and entitled “THERMOELECTRIC GENERATING UNIT AND METHODS OF MAKING AND USING THE SAME,” and as described in greater detail below with reference to FIGS. 10A-16. But it should be understood that the present TEG suitably can be used independently of such a TGU, e.g., can be used with a differently configured TGU, or with another type of thermoelectric device that can convert waste heat into electricity.

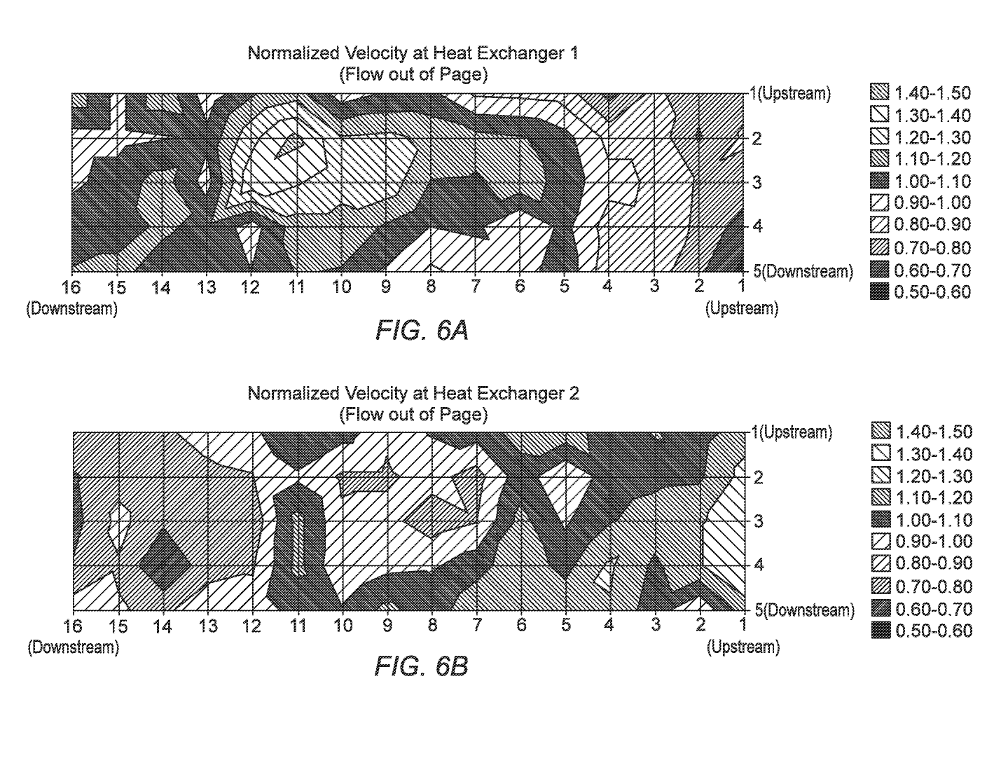

FIGS. 6A-6B illustrate plots of exemplary normalized velocity at different portions of the exemplary thermoelectric system illustrated in FIGS. 5A-5D. More specifically, FIG. 6A illustrates the normalized velocity through second side 513 of tapered inlet manifold 510, and FIG. 6B illustrates the normalized velocity through first side 512 of tapered inlet manifold 510. These results indicate the efficacy of the exhaust transition coupled with the modules in producing substantially even exhaust flow distribution, which is useful for producing maximum power.

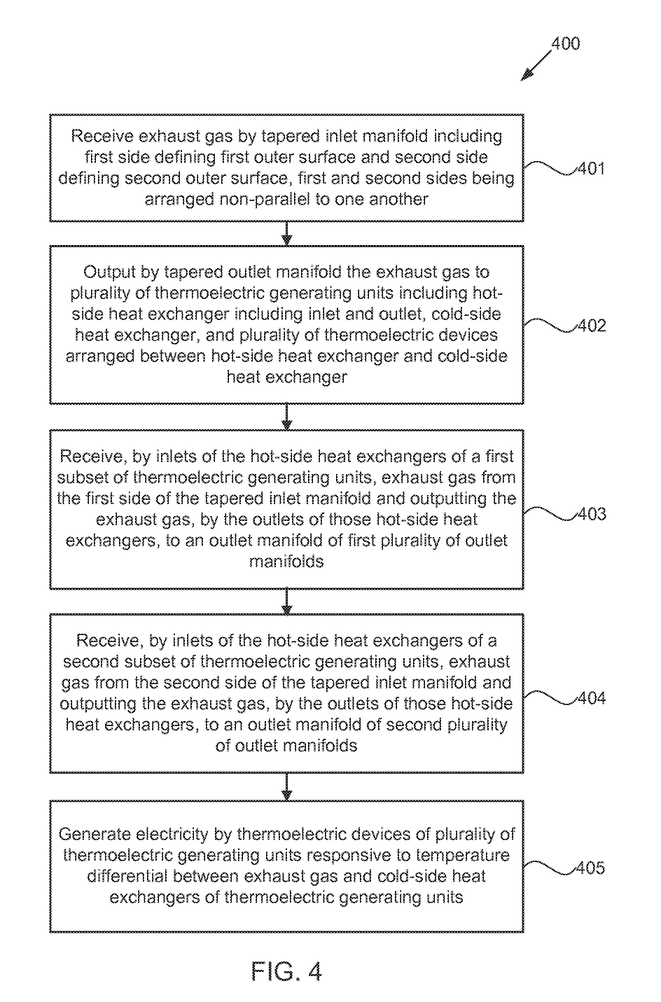

FIG. 4 illustrates steps in an exemplary method for generating electricity using a thermoelectric generator, according to some embodiments. Method 400 illustrated in FIG. 4 includes receiving exhaust gas by a tapered inlet manifold that includes a first side defining a first outer surface of the tapered inlet manifold; and a second side defining a second outer surface of the tapered inlet manifold, the first side and the second side being arranged non-parallel to one another (401). In some embodiments, the tapered inlet manifold can have a configuration such as described herein with reference to FIG. 1A-1B, 2, 3A-3B, or 5A-5D.

Method 400 illustrated in FIG. 4 further includes outputting by the tapered inlet manifold the exhaust gas to a plurality of thermoelectric generating units that each can include a hot-side heat exchanger including an inlet and an outlet; a first cold-side heat exchanger; and a first plurality of thermoelectric devices arranged between the hot-side heat exchanger and the first cold-side heat exchanger (402). In some embodiments, the thermoelectric devices can have a configuration such as described herein with reference to FIG. 1A-1B, 2, 3A-3B, or 5A-5D.

Method 400 illustrated in FIG. 4 further includes receiving, by the inlets of the hot-side heat exchangers of a first subset of the thermoelectric generating units, exhaust gas from the first side of the tapered inlet manifold and outputting the exhaust gas, by the outlets of those hot-side heat exchangers, to an outlet manifold of the first plurality of outlet manifolds (403).

Method 400 illustrated in FIG. 4 further includes receiving, by the inlets of the hot-side heat exchangers of a second subset of the thermoelectric generating units, exhaust gas from the second side of the tapered inlet manifold and outputting the exhaust gas, by the outlets of those hot-side heat exchangers, to an outlet manifold of a second plurality of outlet manifolds (404).

Method 400 illustrated in FIG. 4 further includes generating electricity by the thermoelectric devices of the plurality of thermoelectric generating units responsive to a temperature differential between the exhaust gas and the first cold-side heat exchangers of those thermoelectric generating units (405).

In some embodiments, method 400 includes generating at least about 5 kW of electricity based on the exhaust gas having a temperature between 400° C.-600° C. and a mass flow of the exhaust gas of between 500-1500 g/s.

In some embodiments, the first side and the second side of the tapered inlet manifold are arranged at an angle of between about 5 and 15 degrees relative to one another. In some embodiments, the hot-side heat exchanger of each of the thermoelectric generating units includes a plurality of discrete channels, each of the discrete channels receiving the exhaust gas. In some embodiments, a plurality of the outlets of the hot-side heat exchangers of the thermoelectric generating units of the first subset output the exhaust gas to one outlet manifold of the first plurality of outlet manifolds; and a plurality of the outlets of the hot-side heat exchangers of the thermoelectric generating units of the second subset output the exhaust gas to one outlet manifold of the second plurality of outlet manifolds. In some embodiments, four of the outlets of the hot-side heat exchangers of the thermoelectric generating units of the first subset output the exhaust gas to one outlet manifold of the first plurality of outlet manifolds; and four of the outlets of the hot-side heat exchangers of the thermoelectric generating units of the second subset output the exhaust gas to one outlet manifold of the second plurality of outlet manifolds.

In some embodiments, method 400 further includes pumping a coolant through each of the first cold-side heat exchangers.

In some embodiments, method 400 further includes selectably diverting a flow of the exhaust gas away from the plurality of thermoelectric generating units.

In some embodiments, method 400 includes housing the tapered inlet manifold, the first plurality of outlet manifolds, the second plurality of outlet manifolds, the plurality of thermoelectric generating units, one or more radiators, and power electronics in a single shipping container.

In some embodiments, each thermoelectric generating unit further includes a second cold-side heat exchanger; and a second plurality of thermoelectric devices arranged between the hot-side heat exchanger and the second cold-side heat exchanger, and method 400 further can include generating electricity responsive to a temperature differential between the exhaust gas and the second cold-side heat exchangers.

Method 400 further can include receiving the electricity from the thermoelectric devices by at least one inverter, wherein the electricity generated by the thermoelectric devices is DC electricity, and wherein the at least one inverter converts the DC electricity to AC electricity.

In some embodiments, a first plurality of apertures are defined through the first side and a second plurality of apertures are defined through the second side. Method 400 can include the inlets of the hot-side heat exchangers of the first subset of the thermoelectric generating units receiving the exhaust gas through the first plurality of apertures, and the inlets of the hot-side heat exchangers of the second subset of the thermoelectric generating units receiving the exhaust gas through the second plurality of apertures. In some embodiments, the apertures of the first and second pluralities of apertures are substantially rectangular.

In some embodiments of method 400, the tapered inlet manifold further includes a splitter disposed within the tapered inlet manifold and arranged between the first side and the second side. A plurality of apertures can be defined through the splitter, e.g., the apertures can be substantially circular. Optionally, the splitter can be arranged so as approximately to bisect an angle between the first side and the second side.

In some embodiments, method 400 further includes cracking higher hydrocarbons in diesel exhaust using a diesel oxidation catalyst disposed between the exhaust gas source and the tapered inlet manifold.

In some embodiments, each hot-side heat exchanger includes at least one threaded rod sealingly coupling the hot-side heat exchanger to the inlet manifold.

The following provides a description of one exemplary, nonlimiting embodiment of the present TEG:
Alphabet Energy introduced the world's largest thermoelectric generator today, which captures exhaust heat and turns it into a new source of electricity.
The company's first product, called the E1, attaches to an exhaust stack, and captures waste heat and uses Alphabet's patented thermoelectric materials to convert it to electricity. Thermoelectrics use a heat differential to create electricity; one side is hot, and the other is cold, and the temperature differential between the two forces electrons to create a current.
The product introduction is the first for the mid-stage startup, which was founded in 2009 at Lawrence Berkeley National Laboratory.
While NASA has used thermoelectrics since the 1950s, materials costs made them cost-prohibitive. However, new advancements in silicon and tetrahedrite have led Alphabet to create highly efficient thermoelectric materials using abundant resources. Thermoelectrics are unique because they are solid-state; which means the E1 has no moving parts, no working fluids and requires no maintenance.
“With the E1, waste heat is now valuable,” said Alphabet Energy CEO and Founder Matthew L. Scullin. “Saving fuel has the potential to be one of the biggest levers a company has in reducing operating expenses. With the E1, that potential is finally realized with the world's first waste-heat recovery product that meets the mining's and oil & gas industry's criteria for a simple, strong, and reliable solution.”
The E1 generates up to 25 kW per 1,000 kWe diesel generator, which means 1% energy efficiency. The electricity the E1 creates can power additional hardware and/or augment power to existing systems, reducing electrical load and in turn, reducing fuel consumption and operating costs.
These turnkey systems ship in a single, standard shipping container and save more than 60,000 liters of diesel fuel per year when operating on a 1,000 kW diesel engine.
The E1 requires no engine modifications and is installed during a simple process that involves exhaust coupling and electrical hookup. Standard connection is complete in less than two hours. All updates to the host engine's (or turbine's) exhaust system are performed within a standard engine maintenance service interval and the E1 complies with all major engine manufacturer back pressure limits and warranty specs.
In addition to improving fuel economy and producing high quality electricity, the E1:
   Attenuates engine exhaust noise by up to 23 dBA,
   Reduces engine exhaust heat signatures by up to 30%,
   Reduces diesel emissions: CO₂ −198,000 lbs/yr; NOx −3,306 lbs/yr; CO −343 lbs/yr; HC −103 lbs/yr; PM −52 lbs/yr.
Alphabet Energy's thermoelectric materials are a platform technology with a wide array of potential applications including power generation associated: remote sensors, surveillance, telemetry, automobiles, trucks, locomotives, mining equipment, ships, jet engines, factory exhaust flues, and many more.
Based on groundbreaking materials science R&D at the Lawrence Berkeley National Laboratory in the US, Alphabet Energy has over 50 patents registered or pending. The top caliber team includes many of the top minds in thermoelectrics and materials science and a wealth of experience from the oil & gas, automotive, and power generation industries. Alphabet Energy has raised over $30 million in funding from top investors including TPG and Encana.

The following provides a description of another exemplary, nonlimiting embodiment of the present TEG:
Saving fuel has the potential to be one of the biggest levers a company has in reducing operating expenses. With the E1, that potential is finally realized with the world's first waste-heat recovery product that meets the mining's and oil & gas industry's criteria for a simple, strong, and reliable solution.
When we set out to build the world's first industrial-scale thermoelectric generator, we knew it had to behave as a piece of simple industrial equipment rather than a complex power plant. We put together a team that combined decades of experience in the oil & gas, mining, engine, and burner industries with the brightest minds in solid-state power generation.
We talked to hundreds of customers who spend their days looking for ways to improve operational efficiency and profitability in their businesses, and who have the most demanding technical requirements for equipment in the field.
What resulted was the E1. The E1 takes waste heat from exhaust and simply turns it into electricity. The result is an engine that needs less fuel to deliver the same power.
The E1's benefits are delivered instantly: several percent savings in fuel and a very short payback time on a small amount of up-front capital. The E1 is optimized for continuous engines 800 to 1400 kW in size running diesel or natural gas, but works on any engine or exhaust source.
But what sets the E1 apart is its strength, reliability, and simplicity, requiring virtually no maintenance or operation.
Installation can occur in just 2 hours with almost no up-front scope. Every part needed comes inside the E1's simple and easily transportable 16- or 20-foot shipping container. There are only two points of connection: the E1 flanges directly onto the exhaust pipe, then wiring is then run from the E1 to the site's main breaker.
The E1's operation is simple and reliable. Exhaust from the engine is channeled through 32 modules that generate power, in the solid-state with no moving parts, using Alphabet's proprietary PowerBlocks thermoelectric technology.
The DC electricity is delivered to the pre-packaged power electronics which inverts the power to AC at the same phase and voltage that the engine delivers. The cooled exhaust then flows up and out of the container at about 200 degrees Celsius. All the while, the E1's pre-packaged radiators keep the modules cool.
The modules inside the E1 are revolutionary because they include the only efficient, low-cost thermoelectrics ever made. Like everything in the E1, they've been rigorously tested in the field to ensure at least a 10 year life. They are fully upgradeable, making the E1 the only upgradeable power generator in existence. As Alphabet continues it advances in thermoelectric materials new modules can be swapped in for old ones, in the same system, to generate even more fuel savings.
With the E1, waste heat is now valuable. Some of the smartest, most forward-thinking companies in the world are using Alphabet's thermoelectric generator, and we're excited to be able to help a range of industries reduce their fuel cost and drive operating margins to build more efficient, profitable businesses.

Exemplary Thermoelectric Generating Unit for Use with Thermoelectric Generator

In one nonlimiting example, the present thermoelectric generators can include thermoelectric generating units that include a plurality of thermoelectric devices that are provided in a sandwich-type arrangement that includes a central hot-side heat exchanger that can be configured so as to receive a fluid carrying waste heat, e.g., exhaust from an engine, and two cold-side plates arranged on either side of the hot-side heat exchanger. Some of the thermoelectric devices can be disposed between one side of the hot-side heat exchanger and one of the cold-side plates, and some of the thermoelectric devices can be disposed between the other side of the hot-side heat exchanger and the other cold-side plate. So as to provide for sufficient thermal contact between the thermoelectric devices, the hot-side heat exchanger, and the respective cold-side plates throughout a range of operating temperatures while inhibiting leakage of the fluid carrying waste heat, a plurality of fasteners can be distributed across and can compress the sandwich-type arrangement. For example, the hot-side heat exchanger can include one or more discrete channels, e.g., multiple discrete channels, through which the fluid carrying waste heat can flow, and the fasteners can be arranged outside of the one or more discrete channels, e.g., within gaps between the channels, rather than being disposed through one of the channels, so as to inhibit potential leakage of the fluid out of the hot-side heat exchanger within the thermoelectric generating unit. Additionally, or alternatively, the fasteners can be disposed within gaps between the thermoelectric devices. The cold-side plates can be substantially flat, so that the pressure imposed by the fasteners onto the thermoelectric devices can be relatively even across the thermoelectric generating unit at operating temperature.

FIGS. 10A-10G schematically illustrate views of an exemplary thermoelectric generating unit (TGU) that optionally can be used with a thermoelectric generator such as illustrated in FIGS. 1A-1B and 2, according to some embodiments. For example, TGU 1000 illustrated in FIGS. 10A-1G can correspond to a thermoelectric generating unit (TEG generating unit) of the thermoelectric generating units 340, 350 described herein with reference to FIGS. 3A-3B, e.g., can be coupled to tapered inlet manifold 310 and outlet manifolds 320 or 330, or can correspond to a thermoelectric generating unit (TEG generating unit) of the thermoelectric generating units 540, 550 described herein with reference to FIGS. 5A-5D, e.g., can be coupled to tapered inlet manifold 510 and outlet manifolds 520, 530.

The non-limiting embodiment of TGU 1000 illustrated in FIGS. 10A-10G includes first cold-side plate 1010, hot side heat exchanger 1020, second cold-side plate 1030, first thermoelectric assembly 1060, second thermoelectric assembly 1070, and a plurality of fasteners 1011. As can be seen in FIG. 10C, first thermoelectric assembly 1060 can be disposed between first cold-side plate 1010 and first side 1026 of hot-side heat exchanger 1020, and second thermoelectric assembly 1070 can be disposed between second cold-side plate 1020 and second side 1027 of hot-side heat exchanger 1020. Fasteners 1011 can be disposed through holes that are defined through first cold-side plate 1010, hot side heat exchanger 1020, second cold-side plate 1030, first thermoelectric assembly 1060, and second thermoelectric assembly 1070, and can provide a suitable distribution of forces and pressures over the TGU so as to maintain satisfactory thermal contact between components of the TGU under a variety of operating conditions that can cause different thermal expansions of such components.

In some embodiments, hot-side heat exchanger 1020 includes first side 1026, second side 1027, and one or more discrete channels, e.g., a plurality of discrete channels 1021. Each of the one or more discrete channels 1021 can be configured so as to receive fluid carrying waste heat, e.g., exhaust from an engine. For example, each of the one or more discrete channels 1021 can include a fluidic inlet 1023 and a fluidic outlet 1028 and a lumen that fluidically couples inlet 1023 and outlet 1028 to one another. The lumen can be configured so as to extract heat from a fluid passing therethrough, e.g., in the direction denoted by arrow 1012 illustrated in FIGS. 10A, 10B, and 10G. For example, in some embodiments, hot-side heat exchanger 1020 further can include fins disposed within the lumen of each of the one or more discrete channels 1021. The fins can include any suitable composition. Illustratively, such fins can include, e.g., stainless steel, nickel plated copper, or stainless steel clad copper. Any suitable arrangement, number, and density of fins can be provided so as to facilitate extraction of heat from the fluid passing through the one or more discrete channels 1021. For example, in some embodiments, a density of the fins within each of the one or more discrete channels is at least 12 fins per inch. In one illustrative embodiment, the hot-side heat exchanger includes a high efficiency hot-side heat exchanger. As used herein, “high efficiency hot-side heat exchanger” is intended to mean a hot-side heat exchanger characterized by a thermal resistance of less than about 0.0015 m²K/W, e.g., a thermal resistance of less than about 0.00025 m²K/W.

Additionally, or alternatively, hot-side heat exchanger 1021 optionally can include at least one threaded rod 1024 configured to sealingly couple the hot-side heat exchanger to a pipe flange or other suitable source of a fluid that carries waste heat, e.g., to a tapered inlet manifold such as described herein with reference to FIG. 3A-3B or 5A-5D. For example, in the embodiment illustrated in FIGS. 10A-10G, each of the one or more discrete channels 1021 of heat exchanger 1020 can include four threaded rods, two for coupling front plate 1022 of hot-side heat exchanger 1020 to tapered inlet manifold such as illustrated in FIG. 3A-3B or 5A-5D or to a first region of a pipe flange, and two for coupling back plate 1029 of hot-side heat exchanger to an outlet manifold 320 or 330 such as illustrated in FIG. 3A-3B or 5A-5D or to a second region of the pipe flange. It should be understood that any suitable type, number, and arrangement of fasteners can be used so as to couple hot side heat exchanger 1021 to a source of a fluid that carries waste heat or to an outlet, e.g., outlet manifold.

In some embodiments, first cold-side plate 1010 and second cold-side plate 1030 are substantially flat. By “substantially flat” it is meant that the cold-side plate includes first and second major surfaces that each are substantially planar and parallel to one another, e.g., are characterized by a flatness and planarity specification of about 0.010″ or less across the cold side plate. In some embodiments, first cold-side plate 1010 and second cold-side plate 1030 each are substantially flat over substantially the entire lateral surface of thermoelectric generating unit 1010. In one non-limiting example, each of first cold-side plate 1010 and second cold-side plate 1030 can include a substantially flat slab of a thermally conductive material, such as a metal or a ceramic. Exemplary metals that can be suitable for use in one or both of first cold-side plate 1010 and second cold-side plate 1030 independently can be selected from the group consisting of aluminum, copper, molybdenum, tungsten, copper-molybdenum alloy, stainless steel, and nickel. Exemplary ceramics that can be suitable for use in one or both of first cold-side plate 1010 and second cold-side plate 1030 independently can be selected from the group consisting of silicon carbide, aluminum nitride, alumina, and silicon nitride. In one illustrative embodiment, one of first cold-side plate 1010 and second cold-side plate 1030 can include a metal, e.g., an exemplary metal listed above, and the other of first cold-side plate 1030 and second cold-side plate 1030 can include a ceramic, e.g., an exemplary ceramic listed above. In another illustrative embodiment, both first cold-side plate 1010 and second cold-side plate 1030 can include a metal, e.g., an exemplary metal listed above. In yet another illustrative embodiment, both first cold-side plate 1010 and second cold-side plate 1030 can include a ceramic, e.g., an exemplary ceramic listed above.

Each of the first cold-side plate 1010 and second cold-side plate 1030, e.g., substantially flat slabs, can include a plurality of apertures defined therethrough for respectively receiving fasteners 1011. As one example, the apertures can extend through the entire thickness of each of the substantially flat slabs. As another example, the apertures can extend through only a portion of the thickness of one or both of the substantially flat slabs. In some embodiments, the apertures are arranged in a plurality of rows and a plurality of columns across the surface of each of the substantially flat slabs.

In some embodiments, one or both of substantially flat first cold-side plate 1010 and substantially second cold-side plate 1030 include one or more channels defined therein that are configured to receive a fluidic coolant, e.g., a liquid or gaseous coolant. One or both of first cold-side plate 1010 and second cold-side plate 1030 can include one or more inlets 1013a or 1013b for coolant inflow and one or more outlets 1013b or 1013a for coolant outflow. In one example, the inlet 1013a or 1013b and outlet 1013b or 1013a for first cold-side plate 1010 are on the same side of the first cold-side plate as one another, and the inlet 1033a or 1033b and outlet 1033b or 1033a for second cold-side plate 1030 are on the same side of the second cold-side plate as one another, e.g., so as to facilitate ease of installation and access to the ports.

Additionally, or alternatively, one or both of first cold-side plate 1010 and second cold-side plate 1030 further can include pin fins, straight fins, or offset fins. In some embodiments, the fins can be disposed inside of one or both of first cold-side plate 1010 and second cold-side plate 1030, e.g., can be disposed within channels respectively defined within one or both of first cold-side plate 1010 and second cold-side plate 1030. The fins can be used to provide extended surfaces or increased surface area to increase heat transfer. The fins can also change the hydraulic diameter and alter flow paths causing disruptions to the boundary layer, again increasing heat transfer. In some embodiments, the pin fins optionally can be arranged in an in-line arrangement or in a staggered arrangement. In one non-limiting example, at least one of first cold-side plate 1010 and second cold-side plate 1030 includes a high efficiency cold-side heat exchanger. As used herein, the term “high efficiency cold-side heat exchanger” is intended to mean a cold-side heat exchanger characterized by a thermal resistance of less than about 7.5e-10 m²K/W.

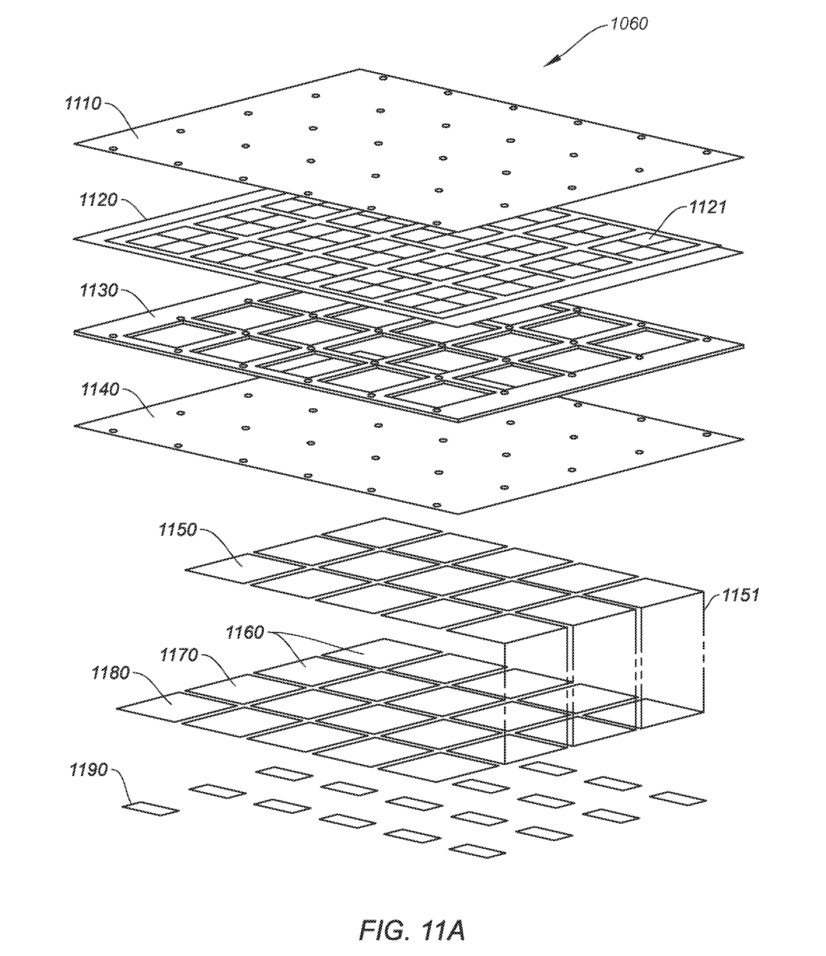

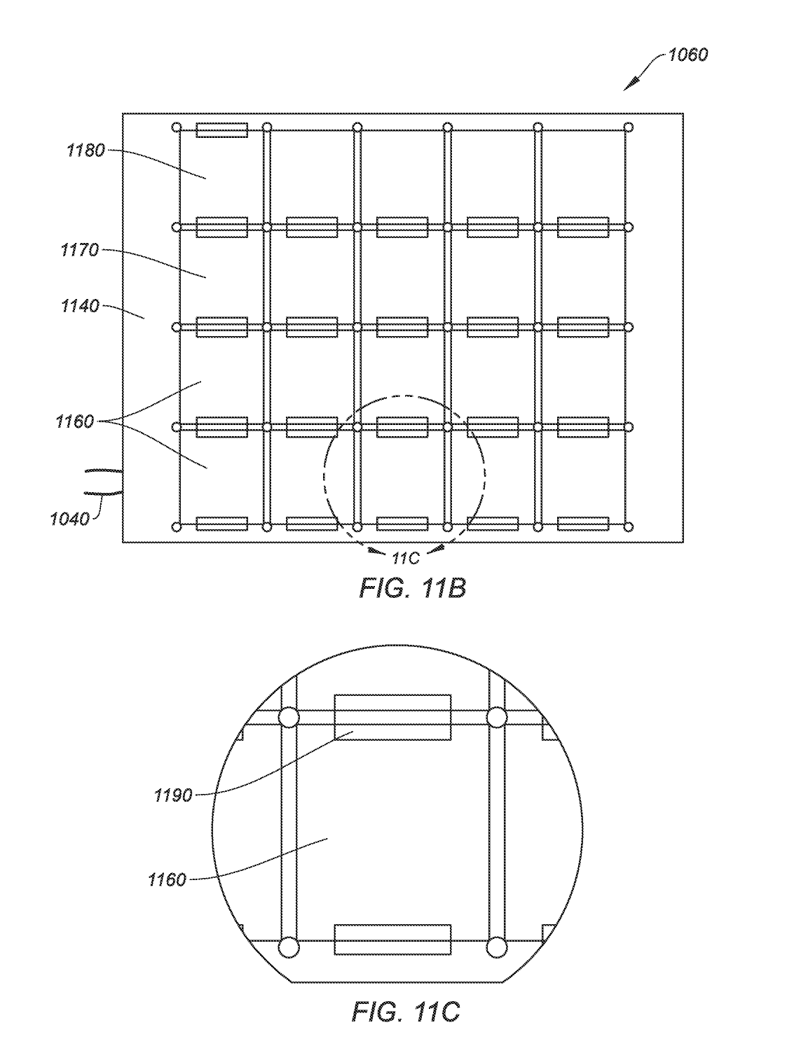

In the embodiment illustrated in FIGS. 10A-10G, thermoelectric generating unit 1000 further includes a first plurality of thermoelectric devices 1061 arranged between first cold-side plate 1010 and first side 1026 of hot-side heat exchanger 1020, and a second plurality of thermoelectric devices 1071 arranged between second cold-side plate 1030 and second side 1027 of hot-side heat exchanger 1020. As one example, first plurality of thermoelectric devices 1061 can be provided as part of first thermoelectric assembly 1060, and second plurality of thermoelectric devices 1071 can be provided as part of second thermoelectric assembly 1070. Exemplary embodiments of thermoelectric assemblies such as suitable for use in one or both of first thermoelectric assembly 1060 and second thermoelectric assembly 1070 are described below with reference to FIGS. 11A-11C. In embodiments such as described in greater detail below with reference to FIGS. 11A-11C, one or both of first plurality of thermoelectric devices 1061 and second plurality of thermoelectric devices 1071 can be disposed on a circuit board.

First plurality of thermoelectric devices 1061 can be arranged in columns and rows between first cold-side plate 1010 and first side 1026 of hot-side heat exchanger 1020, and fasteners 1011 respectively can be disposed within gaps between the columns and rows, e.g., so that the fasteners need not be passed through any of the thermoelectric devices 1061 of the first plurality. Additionally, or alternatively, second plurality of thermoelectric devices 1071 can be arranged in columns and rows between second cold-side plate 1030 and second side 1027 of hot-side heat exchanger 1020, and fasteners 1011 respectively can be disposed within gaps between the columns and rows, e.g., so that the fasteners need not be passed through any of the thermoelectric devices 1071 of the second plurality.

The thermoelectric devices 1061, 1071 of the first and second pluralities of thermoelectric devices can have any suitable configuration. For example, each of the thermoelectric devices 1061, 1071 can include one or more thermoelectric legs, e.g., can include one or more p-type thermoelectric legs and one or more n-type thermoelectric legs. Each of the thermoelectric legs can include a thermoelectric material disposed between first and second conductive materials. The p-type thermoelectric legs can include a different material, or the same material but with different doping, than do the n-type thermoelectric legs. For example, one or both of first plurality 1061 and second plurality 1071 of thermoelectric devices can include a thermoelectric material selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, a half-Heusler compound, or any other thermoelectric material known in the art or yet to be developed. Optionally, one or more of the p-type thermoelectric legs can be connected electrically in series and thermally in parallel with one or more of the n-type thermoelectric legs so as to generate an electrical current responsive to a temperature differential across the assembly. Any suitable number of thermoelectric legs can be provided within each thermoelectric device 1061, 1071. In non-limiting examples, each thermoelectric device can include 1 to 100 p-type thermoelectric legs and 1 to 100 n-type thermoelectric legs, or 10 to 80 p-type thermoelectric legs and 10 to 80 n-type thermoelectric legs, or 20 to 60 p-type thermoelectric legs and 20 to 60 n-type thermoelectric legs, e.g., 48 p-type thermoelectric legs and 48 n-type thermoelectric legs. The number of p-type thermoelectric legs in a thermoelectric device can be, but need not necessarily be, the same as the number of n-type thermoelectric legs in that thermoelectric device.

First plurality of thermoelectric devices 1061 can be electrically connected so as to obtain current therefrom responsive to a temperature differential between hot-side heat exchanger 1020 and first cold-side plate 1010. Second plurality of thermoelectric devices 1071 can be electrically connected so as to obtain current therefrom responsive to a temperature differential between hot-side heat exchanger 1020 and second cold-side plate 1030. In one nonlimiting embodiment, first plurality of thermoelectric devices 1061 is connected electrically in serial with second plurality of thermoelectric devices 1071 using conductor(s) 1040. For example, the exemplary external connections illustrated in FIG. 10F include wiring 1041, 1042, and 1043. Positive wiring 1041 and negative wiring 1042 respectively extend from first thermoelectric assembly 1060 and second thermoelectric assembly 1070. Series wiring 1043 extends from both first thermoelectric assembly 1060 and second thermoelectric assembly 1070 so as to connect assemblies 1060, 1070 electrically in series with one another. The thermoelectric devices respectively of first thermoelectric assembly 1060 and second thermoelectric assembly 1070 are wired in a series-parallel configuration internally.

For further examples of thermoelectric legs, electrical connections, and thermoelectric devices that suitably can be used in the present thermoelectric generating units, see the following references, the entire contents of each of which are incorporated by reference herein: U.S. Pat. No. 8,736,011 entitled “Low thermal conductivity matrices with embedded nanostructures and methods thereof,” U.S. Pat. No. 9,051,175 entitled “Bulk nano-ribbon and/or nano-porous structures for thermoelectric devices and methods for making the same,” U.S. Pat. No. 9,065,017 entitled “Thermoelectric devices having reduced thermal stress and contact resistance, and methods of forming and using the same,” U.S. Pat. No. 9,082,930 entitled “Nanostructured thermoelectric elements and methods of making the same,” U.S. Patent Publication No. 2011/0114146 entitled “Uniwafer thermoelectric modules,” U.S. Patent Publication No. 2012/0152295 entitled “Arrays of filled nanostructures with protruding segments and methods thereof,” U.S. Patent Publication No. 2012/0247527 entitled “Electrode structures for arrays of nanostructures and methods thereof,” U.S. Patent Publication No. 2012/0295074, “Arrays of long nanostructures in semiconductor materials and methods thereof,” U.S. Patent Publication No. 2012/0319082 entitled “Low thermal conductivity matrices with embedded nanostructures and methods thereof,” U.S. Patent Publication No. 2013/0175654 entitled “Bulk nanohole structures for thermoelectric devices and methods for making the same,” U.S. Patent Publication No. 2013/0186445 entitled “Modular thermoelectric units for heat recovery systems and methods thereof,” U.S. Patent Publication No. 2014/0024163 entitled “Method and structure for thermoelectric unicouple assembly,” U.S. Patent Publication No. 2014/0116491 entitled “Bulk-size nanostructured materials and methods for making the same by sintering nanowires,” U.S. Patent Publication No. 2014/0182644 entitled “Structures and methods for multi-leg package thermoelectric devices,” U.S. Patent Publication No. 2014/0193982 entitled “Low thermal conductivity matrices with embedded nanostructures and methods thereof,” U.S. Patent Publication No. 2014/0360546 entitled “Silicon-based thermoelectric materials including isoelectronic impurities, thermoelectric devices based on such materials, and methods of making and using same,” U.S. Patent Publication No. 2015/0147842 entitled “Arrays of filled nanostructures with protruding segments and methods thereof,” U.S. Patent Publication No. 2015/0295074 entitled “Arrays of long nanostructures in semiconductor materials and methods thereof,” U.S. patent application Ser. No. 14/679,837 filed Apr. 6, 2015 and entitled “Flexible lead frame for multi-leg package assembly,” and U.S. patent application Ser. No. 14/682,471 filed Apr. 9, 2015 and entitled “Ultra-long silicon nanostructures, and methods of forming and transferring the same.”

Referring still to FIGS. 10A-10G, thermoelectric generating unit 1000 further can include a plurality of fasteners 1011 extending between first cold-side plate 1010 and second cold-side plate 1030 at respective locations outside of the one or more discrete channels 1021, e.g., between discrete channels 1021, of hot-side heat exchanger 1020. Additionally, or alternatively, fasteners 1011 can be disposed within gaps between the thermoelectric devices 1061 of the first plurality and within gaps between the thermoelectric devices of the second plurality 1071. Fasteners 1011 can be configured so as to compress first plurality of thermoelectric devices 1061 between first cold-side plate 1010 and first side 1026 of hot-side heat exchanger 1020 and also can be configured so as to compress second plurality of thermoelectric devices 1071 between second cold-side plate 1030 and second side 1027 of hot-side heat exchanger 1020.

Any suitable number of fasteners 1011 can be provided relative to the number of thermoelectric devices of first plurality of thermoelectric devices 1061 or second plurality of thermoelectric devices 1071. For example, one, two, three, four, or more than one fastener 1011 can be provided for each thermoelectric device of first plurality of thermoelectric devices 1061 or second plurality of thermoelectric devices 1071. As another example, one, two, three, four, or more than four thermoelectric devices of first plurality of thermoelectric devices 1061 or second plurality of thermoelectric devices 1071 can be provided for each fastener 1011. The non-limiting embodiment of thermoelectric generating unit 1000 illustrated in FIGS. 10A-10G includes four fasteners for every four thermoelectric devices 1061 of the first plurality of thermoelectric devices and for every four thermoelectric devices 1071 of the second plurality of thermoelectric devices. As noted above, thermoelectric devices 1061, 1071 optionally can be arranged in rows and columns. Fasteners 1011 can be arranged in rows and columns that are laterally offset from the rows and columns of thermoelectric devices 1061, 1071 so as to pass between the rows and columns of thermoelectric devices 1061, 1071.

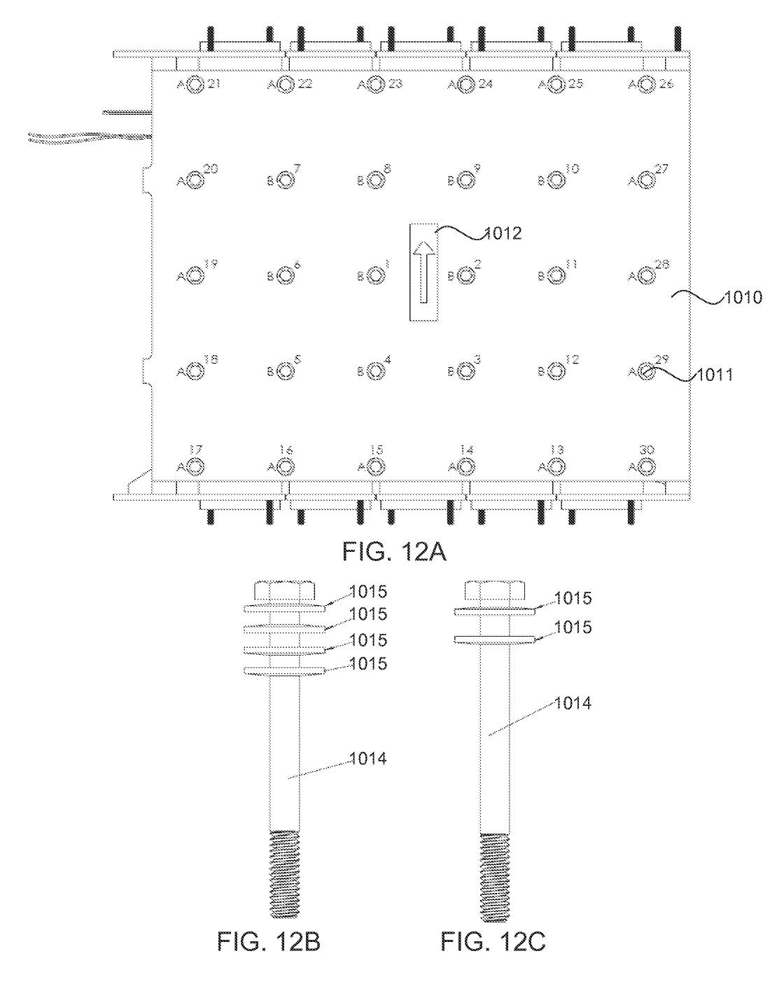

In some embodiments, fasteners 1011 can include a bolt or screw. For example, in embodiments such as illustrated in FIGS. 12B and 12C, fasteners 1011 can include bolt 1014. Optionally, fasteners 1011 also can include a nut that can engage the threading of the bolt or screw so as to comply compression between first cold-side plate 1010 and second cold-side plate 1030. In other embodiments, apertures through one or both of cold-side plate 1010 and second cold-side plate 1030 can include threading that can engage the threading of the bolt or screw so as to apply compression between first cold-side plate 1010 and second cold-side plate 1020. Optionally, fasteners 1011 also can include a spring, a Belleville washer, or a spring washer disposed along the bolt or screw. Illustratively, such a spring, Belleville washer, or spring washer can permit thermal expansion of components of thermal generating unit 1000 with changes in operating temperature, e.g., so as to reduce the likelihood of damage to unit 1000 based on such thermal expansion, while maintaining compression between first cold-side plate 1010 and second cold-side plate 1020. Fasteners 1011 can include different numbers of such springs, Belleville washers, or spring washers disposed along the bolts or screws than one another. For example, in the embodiment illustrated in FIG. 12B, the fastener includes bolt 1014 and four Belleville washers 1015, whereas in the embodiment illustrated in FIG. 12C, the fastener includes bolt 1014 and two Belleville washers. One or more of the springs, Belleville washers, or spring washers can be arranged with opposite orientation to one or more other of the springs, Belleville washers, or spring washers so as to provide additional accommodation for thermal expansion.

In some embodiments, thermoelectric generating unit 1000 optionally includes one or more layers configured to provide thermal insulation, electrical insulation, or both thermal and electrical insulation, between first plurality of thermoelectric devices 1061 and one or both of hot-side heat exchanger 1020 and first cold-side plate 1010, or between second plurality of thermoelectric devices 1071 and one or both of hot-side heat exchanger 1020 and second cold-side plate 1030. Such additional layers are represented in FIG. 10G as elements 1050 and 1080, which can be disposed at any suitable location within thermoelectric generating unit 1000 and can include at least one of the following: a kapton film disposed between first side 1026 of hot-side heat exchanger 1020 and at least one thermoelectric device 1061 of the first plurality of thermoelectric devices; a kapton film disposed between second side 1027 of hot-side heat exchanger 1020 and at least one thermoelectric device 1071 of the second plurality of thermoelectric devices; a kapton film disposed between first cold-side plate 1010 and at least one thermoelectric device 1061 of the first plurality of thermoelectric devices; a kapton film disposed between second cold-side plate 1030 and at least one thermoelectric device 1071 of the second plurality of thermoelectric devices; a mica sheet disposed between first side 1026 of hot-side heat exchanger 1020 and at least one thermoelectric device 1061 of the first plurality of thermoelectric devices; a mica sheet disposed between second side 1027 of hot-side heat exchanger 1020 and at least one thermoelectric device 1071 of the second plurality of thermoelectric devices; a graphite sheet disposed between first side 1026 of hot-side heat exchanger 1020 and at least one thermoelectric device 1061 of the first plurality of thermoelectric devices; a graphite sheet disposed between second side 1027 of hot-side heat exchanger 1020 and at least one thermoelectric device 1071 of the second plurality of thermoelectric devices; a gap pad disposed between first cold-side plate 1010 and at least one thermoelectric device 1061 of the first plurality of thermoelectric devices; a gap pad disposed between second cold-side plate 1030 and at least one thermoelectric device 1071 of the second plurality of thermoelectric devices; an anodized layer disposed between first cold-side plate 1010 and at least one thermoelectric device 1061 of the first plurality of thermoelectric devices; and an anodized layer disposed between second cold-side plate 1030 and at least one thermoelectric device 1071 of the second plurality of thermoelectric devices. Exemplary embodiments of various suitable layer are described below with reference to FIGS. 11A-11C.

Optionally, thermoelectric generating unit 1000 illustrated in FIGS. 10A-10G further can include spacers 1025 disposed between first cold-side plate 1010 and second cold-side plate 1030. In some embodiments, spacers 1025 can include a thermally insulative material that inhibits conduction of heat from hot-side heat exchanger 1020 to one or both of first cold-side plate 1010 and second cold-side plate 1030 except via thermal pathways that pass through the thermoelectric devices 1061, 1071 respectively.

It should be understood that although FIGS. 10A-10G illustrate an embodiment that includes a hot-side heat exchanger and cold-side plates disposed on either side of respective pluralities of thermoelectric devices, other embodiments can include other numbers of hot-side heat exchangers, cold-side plates, and pluralities of thermoelectric devices. One exemplary embodiment can include a hot-side heat exchanger, a cold-side plate, a plurality of thermoelectric devices disposed between the hot-side heat exchanger and a cold-side plate, and a plurality of fasteners arranged so as to compress the plurality of thermoelectric devices. The hot-side heat exchanger, cold-side plate, thermoelectric devices, and fasteners can be arranged similarly as described elsewhere herein.

According to some embodiments, a thermoelectric generating unit (TGU) is a scalable and modular power producing device. In some embodiments, the TGU can be configured in different sizes and shapes so as suitably to fit a package space and/or to improve integration into a thermoelectric generator (TEG) system such as described in the above-mentioned U.S. Provisional Patent Application No. 62/059,092 and as described in greater detail herein, but it should be understood that the present TGU suitably can be used independently of such a TEG, e.g., in a differently configured TEG, in another device, or as a standalone unit. Additionally, the TEG can be used with any suitable TGU, and is not limited to use with the nonlimiting embodiments of TGUs provided herein.

In some embodiments, the present TGU power output is greater than 300 W at inlet temperatures between 450° C. to 600° C. and flows between 25 g/s to 50 g/s. Illustratively, but not necessarily, the physical size of the TGU is 3 ft×3 ft×0.5 ft (10 ft³) or less with a mass of <75 kg. In some embodiments, operating voltage of the TGU can be greater than 300 V with an open circuit voltage which can be greater than 600 V.

In some embodiments, the TGU includes a cold side heat exchanger (CHX) or cold plate (also referred to herein as a cold-side plate) that can include a high performance heat exchanger, which can include one or more pin fins, straight fins, offset fins, or other enhanced heat exchanger constructions. In a nonlimiting example in which the CHX or cold-side plate includes a plurality of pin fins, in some embodiments the pin fins each can be about 0.5 mm in diameter with 0.5 mm spacing relative to one another in an inline configuration (staggered configurations or other arrangements, and other dimensions and spacings, are also possible). In some embodiments, microchannel heat transfer effectively cools the cold side of the TGU. As used herein, the terms “about” and “approximately” are intended to mean plus or minus ten percent of the stated value.

In some embodiments, the CHX or cold-side plate is constructed such that both the inlet and outlet of the coolant flow are on the same side of the plate as one another. In some embodiments, this configuration provides U flow. Illustratively, such a U flow configuration can provide higher flow through the CHX or cold-side plate, which can increase both heat transfer and pressure drop. An illustrative configuration in which both the inlet and outlet of the coolant flow are on the same side of the plate as one another can facilitate easier access to the coolant fluid ports (inlet and outlet) for assembly and maintenance purposes. In some embodiments, in addition to the coolant fluid ports, the electrical connections are also both on the same side of the TGU as one other and as the cooling fluid ports. Illustratively, such a configuration can facilitate all of the connections, both fluid and electrical, to be made on the same side of the TGU (or TEG, in certain embodiments), which can simplify assembly and maintenance procedures.

In some embodiments, dielectric insulation of the TGU can be provided in multiple ways. In one nonlimiting example, dielectric insulation can provided at the powercard or TE (thermoelectric) device level with ceramic substrates partially, substantially, or completely isolating the electrical components from the CHX (cold-side plate) or the hot-side heat exchanger (HHX), or both. Additionally, or alternatively, in some embodiments, e.g., embodiments in which the ceramic substrates are split for thermal expansion mismatch accommodation and/or the TE devices are unsealed, or both, other dielectric protection can be used. For example, the CHX or cold-side plate can be anodized, which can provide a relatively thin, electrically isolating layer. Additionally, or alternatively, another exemplary configuration adds a thin layer of kapton or mica to the thermal interface materials (TIMs) to provide electrical isolation. Illustratively, such a thin layer can be applied to either the hot or cold side TIMs or both sides. Additionally, or alternatively, in some embodiments, voltage leakage from the connections between the TE devices can be inhibited by taping the connections between TE devices with electrical tape or kapton so as to partially, substantially, or completely electrically isolate such connections. Additionally, or alternatively, in some embodiments, a conformal coating can be added so as to partially, substantially, or completely electrically isolate the connections between TE devices.

FIGS. 11A-11C schematically illustrate views of an exemplary thermoelectric assembly for use in a thermoelectric generating unit such as illustrated in FIGS. 10A-10G that optionally can be used with a thermoelectric generator such as illustrated in FIGS. 1A-1B and 2, according to some embodiments. Thermoelectric assembly 1060 illustrated in FIGS. 11A-11C can correspond to one or both of thermoelectric assembly 1060 and thermoelectric assembly 1070 described above with reference to FIGS. 10A-10G.

Thermoelectric assembly 1060 illustrated in FIGS. 11A-11C can include first insulation layer 1110, circuit board 1120 including a plurality of thermoelectric devices 1121 disposed thereon, thermal insulation layer 1130, second insulation layer 1140, third insulation layer 1150, fourth insulation layer 1160, fifth insulation layer 1170, sixth insulation layer 1180, and adhesive 1190.

First insulation layer 1110 can be disposed over circuit board 1120 and can be configured so as to provide thermal insulation, electrical insulation, or both thermal and electrical insulation between thermoelectric devices 1121 disposed on circuit board 1120 and a substantially flat cold-side plate, e.g., first cold-side plate 1010 or second cold-side plate 1030 described above with reference to FIGS. 10A-10G. In one non-limiting embodiment, first insulation layer 1110 includes one or more films of kapton, two or more films of kapton, or three or more films of kapton, e.g., four films of kapton having a thickness of about 0.001 inches each.

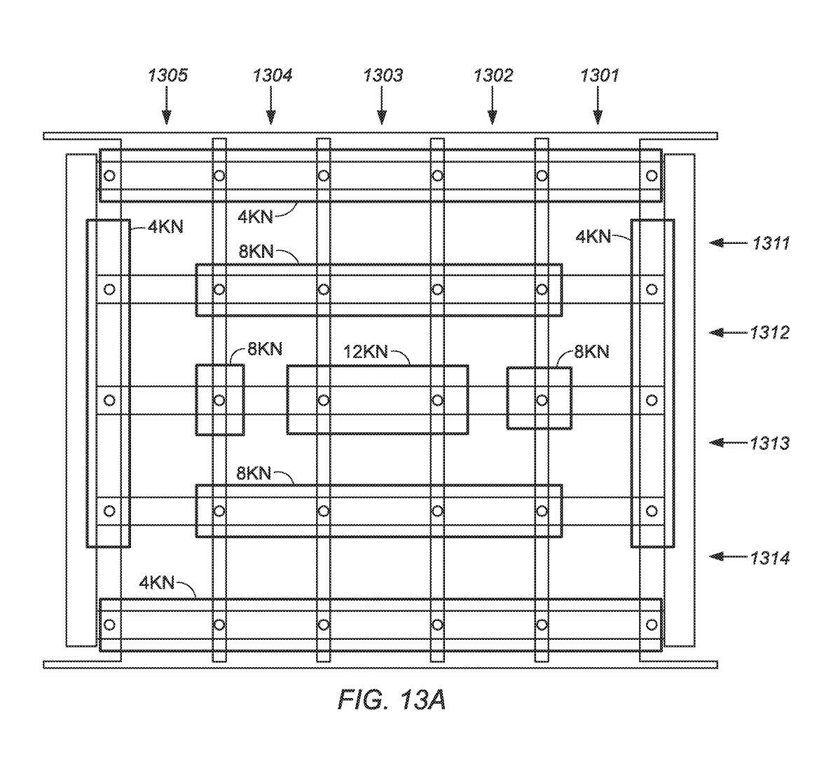

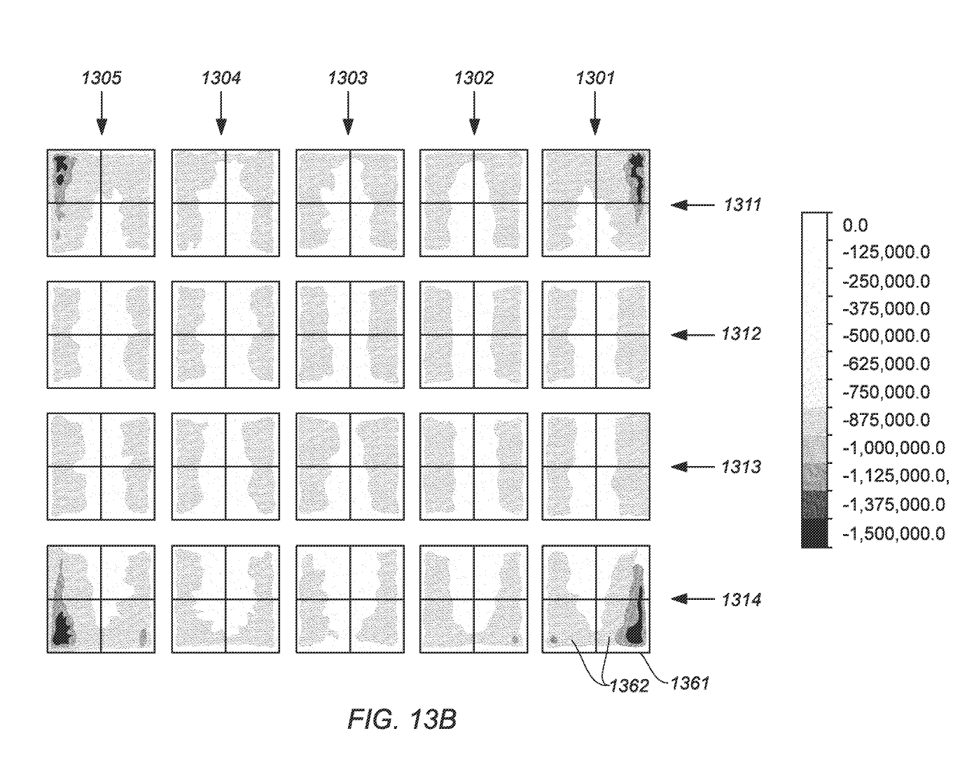

Circuit board 1120 is disposed over thermal insulation layer 1130 and includes a plurality of thermoelectric devices 1121 disposed thereon. The thermoelectric devices 1121 optionally can be grouped together in assemblies that include any suitable number of thermoelectric devices 1121, e.g., one, more than one, more than two, or more than three thermoelectric devices 1121, e.g., four thermoelectric devices. Thermoelectric devices 1121, or the assemblies of thermoelectric devices 1121, can be arranged in columns and rows in a manner such as illustrated in FIGS. 13A-13B.

Thermal insulation layer 1130 can be disposed over second insulation layer 1140 and can include any suitable thermal insulation material that can inhibit heat from being dissipated from the hot side to the cold side without going through thermoelectric devices 1121, and also can inhibit thermal shorting in regions where thermoelectric devices 1121 are not present.

Second insulation layer 1140, third insulation layer 1150, fourth insulation layer 1160, fifth insulation layer 1170, and sixth insulation layer 1180 can be selected so as to provide any suitable degree of thermal insulation, electrical insulation, or both thermal and electrical insulation between circuit board 1120 and thermoelectric devices 1121 disposed therein, and a hot-side heat exchanger, e.g., hot-side heat exchanger 1020 described above with reference to FIGS. 10A-10G. In one non-limiting embodiment, second insulation layer 1140 is disposed over third insulation layer 1150 and includes one or more films of kapton, two or more films of kapton, or three or more films of kapton, e.g., one film of kapton having a thickness of about 0.001 inch. In some embodiments, third insulation layer 1150 is disposed over fourth insulation layer 1160 and fifth insulation layer 1170 and can include one or more graphite sheets, two or more graphite sheets, or three or more graphite sheets, e.g., one graphite sheet having a thickness of about 0.25 inches. The dotted lines at 1151 are intended to indicate the exemplary relative alignment between third insulation layer 1150, fourth insulation layer 1160, and fifth insulation layer 1170. In some embodiments, fourth insulation layer 1160 is disposed adjacent to fifth insulation layer 1170 and under only a subset of thermoelectric devices 1021 (with one or more layers disposed in between), and can include one or more graphite sheets, two or more graphite sheets, or three or more graphite sheets, e.g., one graphite sheet having a thickness of about 0.25 inches. In some embodiments, fifth insulation layer 1170 is disposed adjacent to sixth insulation layer 1180, adjacent to fourth insulation layer 1160, and under only a subset of thermoelectric devices 1021 (with one or more layers disposed in between), and can include one or more mica sheets, two or more mica sheets, or three or more mica sheets, e.g., ten mica sheets having a thickness of about 0.008 inches each. In some embodiments, sixth insulation layer 1180 is disposed adjacent to fifth insulation layer 1170, and under only a subset of thermoelectric devices 1021 (with one or more layers disposed in between), and can include one or more mica sheets, two or more mica sheets, or three or more mica sheets, e.g., seven mica sheets having a thickness of about 0.020 inches each. The mica sheets of fifth insulation layer 1170 and sixth insulation layer 1180 optionally can include a combination of mica and graphite. Adhesive 1190, e.g., kapton tape, can be used to adhere the different insulation layers to one another and to second insulation layer 1140 in a manner such as illustrated in FIGS. 11B-11C.

Note that in the embodiment illustrated in FIG. 11A, sixth insulation layer 1180 can be disposed adjacent to the inlets of the one or more discrete channels of the hot-side heat exchanger, e.g., where the fluid carrying the waste heat can be the hottest. Fifth insulation layer 1170 can be disposed adjacent to a central portion of the one or more discrete channels of the hot-side heat exchanger, e.g., where the fluid carrying the waste heat is cooler than at the inlet. Fourth insulation layer 1160 can be disposed adjacent to the outlets of the one or more discrete channels of the hot-side heat exchanger, e.g., where the fluid carrying the waste heat can be still cooler than in the central portion. Sixth insulation layer 1180 can provide greater thermal insulation between thermoelectric devices 1121 and the hot-side heat exchanger than does fifth insulation layer 1170, an fifth insulation layer 1170 can provide greater thermal insulation between thermoelectric devices 1121 and the hot-side heat exchanger than does fourth insulation 1160. As such, a suitable amount of heat can be transmitted through the respective insulation layer 1160, 1170, or 1180 to the thermoelectric devices 1121 disposed over that layer, while sufficiently protecting the thermoelectric devices 1121 from being damaged by that heat.

Note that the particular arrangement of elements in FIGS. 11A-11C is intended to be purely illustrative, and not limiting. One or more of the insulation layers suitably can be omitted or modified so as to facilitate transfer of heat from the fluid to the thermoelectric devices, while suitably protecting the thermoelectric devices from damage by that heat.

In one exemplary, nonlimiting configuration, the TE devices are connected together on a circuit board or printed wiring harness, so as to reduce the complexity and amount of wiring. In such embodiments, the traces of the circuit board can be properly electrically isolated from one another. In some embodiments, the TGU can include a configuration of clamping bolts that go through the circuit board or wiring harness. In some embodiments, so as to inhibit electrical continuity, contact, or communication between the bolts and the circuit board or wiring harness, the bolts can be electrically isolated, e.g., by applying kapton tape to them and/or a high temperature electrically isolating coating.

An exemplary TGU prepared as provided herein was tested on a hi pot tester, passing at voltages greater than 2 kV. The exemplary TGU was also tested with a mega-ohm meter where fully parallel (all heat exchangers connected together) resistances were measured exceeding 50 Mohm.

In one nonlimiting, illustrative embodiment, the TGU includes two CHX or cold-side plates and one set of hot heat exchanger (HHX) channels sandwiching two sets of TE devices or powercards connected electrically together on a circuit board or printed wiring harness. Illustratively, the fluid flows of the CHX (cold-side plate) and HHX can be configured in a cross flow construction relative to one another, although counter and parallel flow configurations are also options. An alternative construction allows for alternating CHX (cold-side plate) and HHX with the TE circuit board sandwiched in between, and in some embodiments there can be one more CHX (cold-side plate) than HHX set.

In some embodiments, the HHX set includes a plurality of separate HHX channels, e.g., two, three, four, five, six, seven, eight, nine, ten, or more than ten HHX channels, connected fluidically in parallel with one another so as to enhance thermal expansion protection. In some embodiments, such a configuration can reduce thermal stress in the TGU. In some embodiments, hot heat exchangers can experience exemplary temperatures from −40° C. or less to 600° C. or greater. In some embodiments, by separating the hot heat exchangers (channels of the HHX) from one another, the length of the hot heat exchangers can be reduced and therefore the absolute expansion can be reduced. In some embodiments, expansion occurs in between hot heat exchanger channels, which can reduce effects on interface with the rest of the TGU. In some embodiments, such a configuration can increase repeatability of part, thus, in some embodiments, reducing cost through volume. In some embodiments, such a configuration also can improve quality of hot heat exchanger build, e.g., by reducing maximum length of the fin pack, braze surface, and the like. Additionally, the modular configuration of some embodiments can allow for integration into TGUs of various sizes by adding or removing channels.

So as to maintain satisfactory thermal contact between the HHX, cold-side plate(s), and thermoelectric devices, one or more fasteners can be configured so as to apply different forces than one or more other fasteners across the TGU. For example, in certain embodiments of a TGU, e.g., as described above with reference to FIGS. 10A-10G, a first subset of the first plurality of thermoelectric devices 1061 is centrally disposed and a second subset of the first plurality of thermoelectric devices 1071 is peripherally disposed. Illustratively, a first subset of the plurality of fasteners 1011 apply a first force to the first subset of the first plurality of thermoelectric devices and a second subset of the plurality of fasteners 1011 apply a second force to the second subset of the first plurality of thermoelectric devices, where the first force is greater than the second force. In one nonlimiting example, the first force is at least 1.5 times the second force. Optionally, in some embodiments, a third subset of the first plurality of thermoelectric devices 1061 can be disposed between the first subset of the first plurality of thermoelectric devices 1061 and the third subset of the first plurality of thermoelectric devices 1061. A third subset of the plurality of fasteners 1011 apply a third force to the third subset of the first plurality of thermoelectric devices 1061, where the third force is less than the first force and greater than the second force. In one nonlimiting example, the first force is about 1.5 times the third force, and the first force is about 3 times the second force. Illustratively, the first force can be about 11-13 kN, the third force can be about 7-9 kN, and the second force can be about 3-5 kN. In some embodiments, such a distribution of forces can provide a substantially uniform pressure of the TGU, e.g., a substantially uniform pressure of 80 psi across the TGU.

For example, in some embodiments, the bolt pattern for the TGU layout utilizes unequal bolt torqueing. In some embodiments, controlling interface pressure at hot and cold junctions of the TGU can be useful so as to enhance performance. In some embodiments, by reducing distance between bolts, pressure can be controlled locally. In some embodiments, bolt loading is selected so as to account for, or to offset, stiffness effects of other TGU components. For example, as noted further above, fasteners 1011 can include a bolt or screw, and also can include a spring, a Belleville washer, or a spring washer disposed along the bolt or screw. Illustratively, such a spring, Belleville washer, or spring washer can permit thermal expansion of components of thermal generating unit 1000 with changes in operating temperature, e.g., so as to reduce the likelihood of damage to unit 1000 based on such thermal expansion, while maintaining compression between first cold-side plate 1010 and second cold-side plate 1020. Referring again to the above-mentioned subsets, the first subset of the plurality of fasteners optionally can include a greater number of springs, Belleville washers, or spring washers disposed along the bolts or screws of that subset than does the second subset of the plurality of fasteners.

For example, FIGS. 12A-12C schematically illustrate exemplary arrangements of fasteners for use in a thermoelectric generating unit such as illustrated in FIGS. 10A-10G that optionally can be used with a thermoelectric generator such as illustrated in FIGS. 1A-1B and 2, according to some embodiments. FIG. 12A illustrates a top view of first cold-side plate 1010 similar to that described above with reference to FIGS. 10A-10G, with annotations representing an exemplary fastener configuration at different locations through first cold-side plate 1010. More specifically, in FIG. 12A, the annotation “A” indicates that the fastener configuration illustrated in FIG. 12B is used, and the annotation “B” indicates that the fastener configuration illustrated in FIG. 12C is used. The annotations 1-30 indicate the number designation of the respective fasteners. Table 1 below summarizes one exemplary set of torques that can be applied to the various fasteners (e.g., bolts) represented in FIG. 12A on different passes:

TABLE 1
SPECIFICATION: BOLT TORQUE (IN-LBS)

| BOLT # | PASS #1 | PASS #2 | PASS #3 | PASS #4 | PASS #5 |
|---|---|---|---|---|---|
| 1-2 | 30 | 60 | 90 | 120 | 120 |
| 3-12 | 20 | 40 | 60 | 80 | 80 |
| 13-30 | 10 | 20 | 30 | 40 | 40 |

FIG. 13A schematically illustrates one nonlimiting example of an arrangement of fasteners for use in a thermoelectric generating unit such as illustrated in FIGS. 10A-10G that optionally can be used with a thermoelectric generator such as illustrated in FIGS. 1A-1B and 2, according to some embodiments. For example, FIG. 13A illustrates a schematic showing one exemplary embodiment in which unequal fastener (bolt) torque values can be used to create a partially, substantially, or completely uniform pressure on or across some or all of the TE devices of the TGU. In FIG. 13A, a force of about 12 kN is applied to a first subset of thermoelectric devices that is centrally disposed, a force of about 4 kN is applied to a second subset of thermoelectric devices that is peripherally disposed, and a force of about 8 kN is applied to a third subset of thermoelectric devices that is disposed between the first subset and the second subset. FIG. 13B schematically illustrates one nonlimiting example of a distribution of pressures that can be obtained using the arrangement of fasteners illustrated in FIG. 13A. For example, FIG. 13B illustrates exemplary simulation results showing substantial pressure uniformity on each of the TE devices in the circuit board in the TGU based on the nonlimiting, exemplary bolt torque values illustrated in FIG. 13A. In FIG. 13B, it can be seen that each assembly 1361 includes four TE devices 1362. Additionally, in FIGS. 13A and 13B, it can be seen that the assemblies are arranged in columns 1301-1305 and rows 1311-1314 and that the fasteners are disposed between the columns and rows.

Additionally, or alternatively, in some embodiments, the thermal interface along the length of the HHX in the flow direction can be varied. Such a configuration can facilitate the use of the TGU in higher temperature exhaust applications by reducing the TE junction temperature at the hottest location below its upper limit. Such a configuration also can improve consistency of the hot junction temperature of the TE devices, e.g., can partially, substantially, or completely equalize the hot junction temperature of the TE devices, such that the TE devices can operate at a suitable load, illustratively, at an optimal load.

Additionally, or alternatively, in some embodiments, compact thermal expansion management is utilized. For example, in some embodiments, the TGU can undergo thermal expansion during operation (such expansion can be steady state or cyclic, or both steady state and cyclic). In some embodiments, the incorporation of Belleville washers can facilitate bolt (fastener) loads—and therefore pressure on the TE devices—to remain relatively stable over a portion of or over the entire operating range of the TGU. In some embodiments, a gap pad can be used as an interface between CHX and a cold junction of thermal interface material, and in some embodiments, such gap pad can be made thicker than thermally necessary so as to partially, substantially, or completely absorb some of such expansion.

Additionally, or alternatively, in some embodiments, strategic heat transfer fin location can be utilized within either the HHX and/or the CHX so as to enhance localized heat transfer and to reduce heat exchanger pressure drop. For example, TE devices need not necessarily be located across the entire area of an HHX and/or CHX. In some embodiments, fins are located where needed, and need not necessarily be located where fins are not needed. In addition, in some embodiments, fin density can be varied in different areas of the TGU so as to enhance thermal impedance match in different areas of the TGU.

Additionally, or alternatively, in some embodiments, tortuous path sealing can be utilized so as to inhibit exhaust gas leakage within the TGU. In one nonlimiting example, scallop and gusset features can be utilized so as to inhibit exhaust gas leakage.

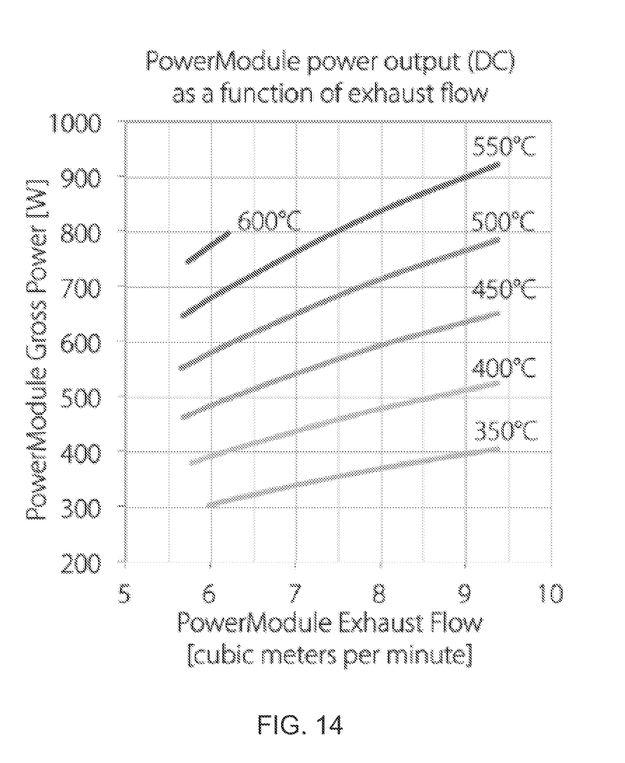

FIG. 14 illustrates a plot of exemplary power output as a function of exhaust flow for a thermoelectric generating unit such as illustrated in FIGS. 10A-10G that optionally can be used with a thermoelectric generator such as illustrated in FIGS. 1A-1B and 2, according to some embodiments. In FIG. 14, it can be understood that based upon an increase in the exhaust flow through the hot-side heat exchanger of the present thermoelectric generating unit (“PowerModule”), the gross power produced by the thermoelectric generating unit increases. Additionally, in FIG. 14, it can be understood that based upon an increase in the inlet temperature of the exhaust flow through the hot-side heat exchanger of the present thermoelectric generating unit (“PowerModule”), the gross power produced by the thermoelectric generating unit increases.

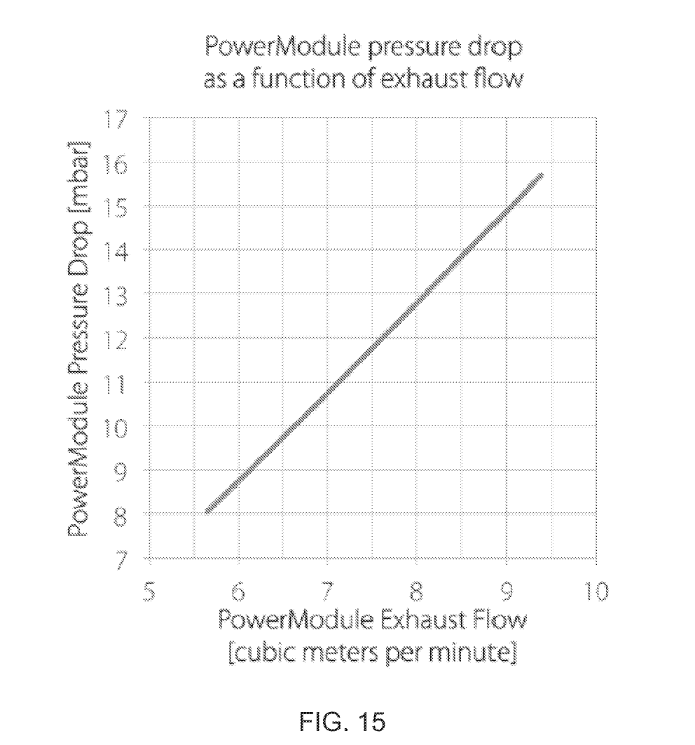

FIG. 15 illustrates a plot of exemplary pressure drop as a function of exhaust flow for a thermoelectric generating unit such as illustrated in FIGS. 10A-10G that optionally can be used with a thermoelectric generator such as illustrated in FIGS. 1A-1B and 2, according to some embodiments. In FIG. 15, it can be understood that based upon an increase in the exhaust flow through the hot-side heat exchanger of the present thermoelectric generating unit (“PowerModule”), the pressure drop within the thermoelectric generating unit increases.

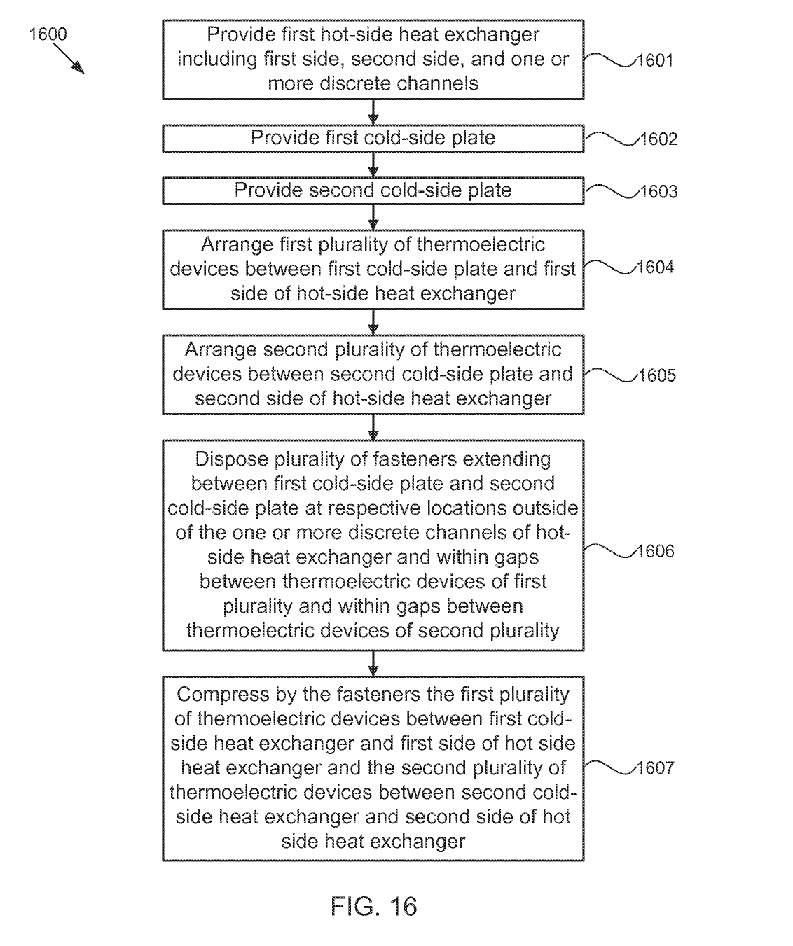

FIG. 16 schematically illustrates steps in an exemplary method of preparing a thermoelectric generating unit, according to some embodiments. Method 1600 includes providing a hot-side heat exchanger including a first side, a second side, and one or more discrete channels (1601). Exemplary embodiments of hot-side heat exchangers are provided elsewhere herein, e.g., with reference to FIGS. 10A-10G.

Method 1600 illustrated in FIG. 16 also includes providing a substantially flat first cold-side plate (1602) and providing a substantially flat second cold-side plate (1603). Exemplary embodiments of cold-side plates are provided elsewhere herein, e.g., with reference to FIGS. 10A-10G.

Method 1600 illustrated in FIG. 16 also includes arranging a first plurality of thermoelectric devices between the first cold-side plate and the first side of the hot-side heat exchanger (1604) and arranging a second plurality of thermoelectric arranged between the second cold-side plate and the second side of hot-side heat exchanger (1605). Exemplary arrangements of thermoelectric devices between a cold-side plate and a heat exchanger are provided elsewhere herein, e.g., with reference to FIGS. 10A-10G, 11A-11C, 12A, and 13A-13B.

Method 1600 illustrated in FIG. 16 also includes disposing a plurality of fasteners extending between the first cold-side plate and the second cold-side plate at respective locations outside of the one or more discrete channels of the hot-side heat exchanger and within gaps between the thermoelectric devices of the first plurality and within gaps between the thermoelectric devices of the second plurality (1606). Exemplary arrangements and configurations of fasteners are provided elsewhere herein, e.g., with reference to FIGS. 10A-10G, 12A-12C, and 13A-13B.

Method 1600 illustrated in FIG. 16 further includes compressing by the fasteners the first plurality of thermoelectric devices between the first cold-side plate and the first side of the hot-side heat exchanger and the second plurality of thermoelectric devices between the second cold-side plate and the second side of the hot-side heat exchanger (1607). Exemplary torques with which the fasteners can be tightened and exemplary forces and pressures that can be exerted by such fasteners are provided elsewhere herein, e.g., with reference to FIGS. 10A-10G, 12A-12C, and 13A-13B.

Optionally, method 1600 includes centrally disposing a first subset of the first plurality of thermoelectric devices; peripherally disposing a second subset of the first plurality of thermoelectric devices; applying a first force to the first subset of the first plurality of thermoelectric devices with a first subset of the plurality of fasteners; and applying a second force to the second subset of the first plurality of thermoelectric devices with a second subset of the plurality of fasteners, wherein the first force is greater than the second force, e.g., in a manner such as described above with reference to FIGS. 12A-12C and 13A-13B. In one non-limiting example, the first force is at least 1.5 times the second force. In some embodiments of method 1600 illustrated in FIG. 16, each fastener can include a bolt or screw; and a spring, a Belleville washer, or a spring washer disposed along the bolt or screw. Optionally, the first subset of the plurality of fasteners includes a greater number of springs, Belleville washers, or spring washers disposed along the bolts or screws of that subset than does the second subset of the plurality of fasteners.

Method 1600 optionally also can include disposing a third subset of the first plurality of thermoelectric devices is between the first subset of the first plurality of thermoelectric devices and the third subset of the first plurality of thermoelectric devices; and applying a third force to the third subset of the first plurality of thermoelectric devices with a third subset of the plurality of fasteners, wherein the third force is less than the first force and greater than the second force, e.g., in a manner such as described above with reference to FIGS. 12A-12C and 13A-13B. In one non-limiting example, the first force can be about 1.5 times the third force, and the first force can be about 3 times the second force. For example, the first force can be about 11-13 kN, the third force can be about 7-9 kN, and the second force can be about 3-5 kN. In some embodiments, such a distribution of forces can provide a substantially uniform pressure of the TGU, e.g., a substantially uniform pressure of 80 psi across the TGU.

Some embodiments of method 1600 further include arranging the first plurality of thermoelectric devices in columns and rows between the first cold-side plate and the first side of the hot-side heat exchanger; and respectively disposing the fasteners within gaps between the columns and rows. In one nonlimiting example, method 1600 can include disposing four fasteners for every four thermoelectric devices of the first plurality of thermoelectric devices and for every four thermoelectric devices of the second plurality of thermoelectric devices. But it should be understood that other numbers of fasteners suitably can be used.

In some embodiments of method 1600, the hot-side heat exchanger further includes fins disposed within each of the one or more discrete channels. Optionally, the fins can include stainless steel, nickel plated copper, or stainless steel clad copper. Optionally, a density of the fins within each of the one or more discrete channels is at least 12 fins per inch.

In some embodiments of method 1600, the hot-side heat exchanger includes at least one threaded rod, and method 1600 further can include sealingly coupling the hot-side heat exchanger to a pipe flange via the at least one threaded rod.

In some embodiments of method 1600, the first cold-side plate further includes pin fins, straight fins, or offset fins. Optionally, the pin fins can be arranged in an in-line arrangement or in a staggered arrangement, or include brazed offset pin fins.

Some embodiments of method 1600 further include disposing the first plurality of thermoelectric devices on a circuit board.

In some embodiments of method 1600, the first plurality of thermoelectric devices include a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

In some embodiments of method 1600, at least one of the first cold-side plate and the second cold-side plate includes a high efficiency cold-side heat exchanger; and the hot-side heat exchanger includes a high efficiency hot-side heat exchanger.

In some embodiments of method 1600, the first cold-side plate includes an inlet for coolant inflow and an outlet for coolant outflow, wherein the inlet and outlet are on the same side of the first cold-side plate as one another.

Some embodiments of method 1600 further include at least one of the following: disposing a kapton film between the first side of the hot-side heat exchanger and at least one thermoelectric device of the first plurality of thermoelectric devices; disposing a kapton film between the first cold-side plate and at least one thermoelectric device of the first plurality of thermoelectric devices; disposing a mica sheet between the first side of the hot-side heat exchanger and at least one thermoelectric device of the first plurality of thermoelectric devices; disposing a graphite sheet between the first side of the hot-side heat exchanger and at least one thermoelectric device of the first plurality of thermoelectric devices; disposing a gap pad between the cold-side plate and at least one thermoelectric device of the first plurality of thermoelectric devices; and disposing an anodized layer between the cold-side plate and at least one thermoelectric device of the first plurality of thermoelectric devices.

### Other Alternative Embodiments

In another example, a thermoelectric generator includes a tapered inlet manifold configured to be coupled to an exhaust gas source. The tapered inlet manifold can include a first side defining a first outer surface of the tapered inlet manifold; and a second side defining a second outer surface of the tapered inlet manifold. The first side and the second side can be arranged non-parallel to one another. The thermoelectric generator further can include a first plurality of outlet manifolds; a second plurality of outlet manifolds; and a plurality of thermoelectric generating units. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. A first subset of the thermoelectric generating units can be coupled to the first side of the tapered inlet manifold such that the inlet of the hot-side heat exchanger of each thermoelectric generating unit of the first subset receives exhaust gas from the tapered inlet manifold and the outlet of that hot-side heat exchanger is coupled to an outlet manifold of the first plurality of outlet manifolds. A second subset of the thermoelectric generating units can be coupled to the second side of the tapered inlet manifold such that the hot-side heat exchanger of each thermoelectric generating unit of the second subset receives exhaust gas from the tapered inlet manifold and the outlet of that hot-side heat exchanger is coupled to an outlet manifold of the second plurality of outlet manifolds. The thermoelectric devices of the plurality of thermoelectric generating units can generate electricity responsive to a temperature differential between the exhaust gas and the first cold-side heat exchangers. Non-limiting examples of such an embodiment are provided herein, e.g., with reference to FIGS. 1A-1B, 2, 3A, 3B, and 5A-5D.

In another example, a method of generating electricity includes receiving exhaust gas by a tapered inlet manifold. The tapered inlet manifold can include a first side defining a first outer surface of the tapered inlet manifold; and a second side defining a second outer surface of the tapered inlet manifold. The first side and the second side can be arranged non-parallel to one another. The method further can include outputting by the tapered inlet manifold the exhaust gas to a plurality of thermoelectric generating units. Each thermoelectric generating unit can include a hot-side heat exchanger including an inlet and an outlet; a first cold-side heat exchanger; and a first plurality of thermoelectric devices arranged between the hot-side heat exchanger and the first cold-side heat exchanger. A first subset of the thermoelectric generating units can be coupled to the first side of the tapered inlet manifold such that the inlet of the hot-side heat exchanger of each thermoelectric generating unit of the first subset receives exhaust gas from the tapered inlet manifold and the outlet of that hot-side heat exchanger is coupled to an outlet manifold of the first plurality of outlet manifolds. A second subset of the thermoelectric generating units can be coupled to the second side of the tapered inlet manifold such that the hot-side heat exchanger of each thermoelectric generating unit of the second subset receives exhaust gas from the tapered inlet manifold and the outlet of that hot-side heat exchanger is coupled to an outlet manifold of the second plurality of outlet manifolds. The method further can include generating electricity by the thermoelectric devices of the plurality of thermoelectric generating units responsive to a temperature differential between the exhaust gas and the first cold-side heat exchangers. Non-limiting examples of such an embodiment are provided herein, e.g., with reference to FIGS. 1A-1B, 2, 3A-3B, 4, 5A-5D, and 6A-6B.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed:

1. A thermoelectric generator, comprising:
a tapered inlet manifold configured to be coupled to an exhaust gas source, the tapered inlet manifold comprising:
a first side defining a first outer surface of the tapered inlet manifold; and
a second side defining a second outer surface of the tapered inlet manifold,
the first side and the second side being arranged non-parallel to one another;
a first plurality of outlet manifolds;
a second plurality of outlet manifolds; and
a plurality of thermoelectric generating units, each thermoelectric generating unit comprising:
a hot-side heat exchanger including an inlet and an outlet;
a first cold-side heat exchanger; and
a first plurality of thermoelectric devices arranged between the hot-side heat exchanger and the first cold-side heat exchanger;
a first subset of the thermoelectric generating units being coupled to the first side of the tapered inlet manifold such that the inlet of the hot-side heat exchanger of each thermoelectric generating unit of the first subset receives exhaust gas from the first side of the tapered inlet manifold and the outlet of that hot-side heat exchanger is coupled to an outlet manifold of the first plurality of outlet manifolds;
a second subset of the thermoelectric generating units being coupled to the second side of the tapered inlet manifold such that the hot-side heat exchanger of each thermoelectric generating unit of the second subset receives exhaust gas from the second side of the tapered inlet manifold and the outlet of that hot-side heat exchanger is coupled to an outlet manifold of the second plurality of outlet manifolds;
the thermoelectric devices of the plurality of thermoelectric generating units generating electricity responsive to a temperature differential between the exhaust gas and the first cold-side heat exchangers.

2. The generator of claim 1, comprising a sufficient number of the thermoelectric generating units to generate at least about 5 kW of electricity based on the exhaust gas having a temperature between 400° C.-600° C. and a mass flow of the exhaust gas of between 500-1500 g/s.

3. The generator of claim 1, wherein the first side and the second side of the tapered inlet manifold are arranged at an angle of between about 5 and 15 degrees relative to one another.

4. The generator of claim 1, wherein the hot-side heat exchanger of each of the thermoelectric generating units includes a plurality of discrete channels, each of the discrete channels receiving the exhaust gas.

5. The generator of claim 1, wherein a plurality of the outlets of the hot-side heat exchangers of the thermoelectric generating units of the first subset are coupled to one outlet manifold of the first plurality of outlet manifolds; and
wherein a plurality of the outlets of the hot-side heat exchangers of the thermoelectric generating units of the second subset are coupled to one outlet manifold of the second plurality of outlet manifolds.

6. The generator of claim 5, wherein four of the outlets of the hot-side heat exchangers of the thermoelectric generating units of the first subset are coupled to one outlet manifold of the first plurality of outlet manifolds; and
wherein four of the outlets of the hot-side heat exchangers of the thermoelectric generating units of the second subset are coupled to one outlet manifold of the second plurality of outlet manifolds.

7. The generator of claim 1, wherein each of the first cold-side heat exchangers is coupled to a coolant system configured to pump a coolant through the first cold-side heat exchangers.

8. The generator of claim 1, further comprising a diverter valve configured so as to selectably divert a flow of the exhaust gas away from the plurality of thermoelectric generating units.

9. The generator of claim 1, further comprising a single shipping container housing the tapered inlet manifold, the first plurality of outlet manifolds, the second plurality of outlet manifolds, the plurality of thermoelectric generating units, one or more radiators, and power electronics.

10. The generator of claim 1, wherein each thermoelectric generating unit further comprises:
a second cold-side heat exchanger; and
a second plurality of thermoelectric devices arranged between the hot-side heat exchanger and the second cold-side heat exchanger.

11. The generator of claim 1, further comprising at least one inverter receiving the electricity from the thermoelectric devices,
wherein the electricity generated by the thermoelectric devices is DC electricity,
wherein the at least one inverter converts the DC electricity to AC electricity.

12. The generator of claim 1, wherein a first plurality of apertures are defined through the first side and a second plurality of apertures are defined through the second side.

13. The generator of claim 12, wherein the inlets of the hot-side heat exchangers of the first subset of the thermoelectric generating units receive the exhaust gas through the first plurality of apertures, and
wherein the inlets of the hot-side heat exchangers of the second subset of the thermoelectric generating units receive the exhaust gas through the second plurality of apertures.

14. The generator of claim 12, wherein the apertures of the first and second pluralities of apertures are substantially rectangular.

15. The generator of claim 1, wherein the tapered inlet manifold further includes a splitter disposed within the tapered inlet manifold and arranged between the first side and the second side.

16. The generator of claim 15, wherein a plurality of apertures are defined through the splitter.

17. The generator of claim 15, wherein the apertures are substantially circular.

18. The generator of claim 15, wherein the splitter is arranged so as approximately to bisect an angle between the first side and the second side.

19. The generator of claim 1, further comprising a diesel oxidation catalyst disposed between the exhaust gas source and the tapered inlet manifold.

20. The generator of claim 1, wherein each hot-side heat exchanger includes at least one threaded rod sealingly coupling the hot-side heat exchanger to the inlet manifold.

21. A method of generating electricity, comprising:
receiving exhaust gas by a tapered inlet manifold, the tapered inlet manifold comprising:
a first side defining a first outer surface of the tapered inlet manifold; and
a second side defining a second outer surface of the tapered inlet manifold,
the first side and the second side being arranged non-parallel to one another;
outputting by the tapered inlet manifold the exhaust gas to a plurality of thermoelectric generating units, each thermoelectric generating unit comprising:
a hot-side heat exchanger including an inlet and an outlet;
a first cold-side heat exchanger; and
a first plurality of thermoelectric devices arranged between the hot-side heat exchanger and the first cold-side heat exchanger;
receiving, by the inlets of the hot-side heat exchangers of a first subset of the thermoelectric generating units, exhaust gas from the first side of the tapered inlet manifold and outputting the exhaust gas, by the outlets of those hot-side heat exchangers, to an outlet manifold of a first plurality of outlet manifolds;
receiving, by the inlets of the hot-side heat exchangers of a second subset of the thermoelectric generating units, exhaust gas from the second side of the tapered inlet manifold and outputting the exhaust gas, by the outlets of those hot-side heat exchangers, to an outlet manifold of a second plurality of outlet manifolds; and
generating electricity by the thermoelectric devices of the plurality of thermoelectric generating units responsive to a temperature differential between the exhaust gas and the first cold-side heat exchangers of those thermoelectric generating units.

22. The method of claim 21, comprising generating at least about 5 kW of electricity based on the exhaust gas having a temperature between 400° C.-600° C. and a mass flow of the exhaust gas of between 500-1500 g/s.

23. The method of claim 21, wherein the first side and the second side of the tapered inlet manifold are arranged at an angle of between about 5 and 15 degrees relative to one another.

24. The method of claim 21, wherein the hot-side heat exchanger of each of the thermoelectric generating units includes a plurality of discrete channels, each of the discrete channels receiving the exhaust gas.

25. The method of claim 21, wherein a plurality of the outlets of the hot-side heat exchangers of the thermoelectric generating units of the first subset output the exhaust gas to one outlet manifold of the first plurality of outlet manifolds; and
wherein a plurality of the outlets of the hot-side heat exchangers of the thermoelectric generating units of the second subset output the exhaust gas to one outlet manifold of the second plurality of outlet manifolds.

26. The method of claim 25, wherein four of the outlets of the hot-side heat exchangers of the thermoelectric generating units of the first subset output the exhaust gas to one outlet manifold of the first plurality of outlet manifolds; and
wherein four of the outlets of the hot-side heat exchangers of the thermoelectric generating units of the second subset output the exhaust gas to one outlet manifold of the second plurality of outlet manifolds.

27. The method of claim 21, further comprising pumping a coolant through each of the first cold-side heat exchangers.

28. The method of claim 21, further comprising selectably diverting a flow of the exhaust gas away from the plurality of thermoelectric generating units.

29. The method of claim 21, further comprising housing the tapered inlet manifold, the first plurality of outlet manifolds, the second plurality of outlet manifolds, the plurality of thermoelectric generating units, one or more radiators, and power electronics in a single shipping container.

30. The method of claim 21, wherein each thermoelectric generating unit further comprises:
a second cold-side heat exchanger; and
a second plurality of thermoelectric devices arranged between the hot-side heat exchanger and the second cold-side heat exchanger, the method further comprising generating electricity responsive to a temperature differential between the exhaust gas and the second cold-side heat exchangers.

31. The method of claim 21, further comprising receiving the electricity from the thermoelectric devices by at least one inverter,
wherein the electricity generated by the thermoelectric devices is DC electricity,
wherein the at least one inverter converts the DC electricity to AC electricity.

32. The method of claim 21, wherein a first plurality of apertures are defined through the first side and a second plurality of apertures are defined through the second side.

33. The method of claim 32, wherein the inlets of the hot-side heat exchangers of the first subset of the thermoelectric generating units receive the exhaust gas through the first plurality of apertures, and
wherein the inlets of the hot-side heat exchangers of the second subset of the thermoelectric generating units receive the exhaust gas through the second plurality of apertures.

34. The method of claim 32, wherein the apertures of the first and second pluralities of apertures are substantially rectangular.

35. The method of claim 21, wherein the tapered inlet manifold further includes a splitter disposed within the tapered inlet manifold and arranged between the first side and the second side.

36. The method of claim 35, wherein a plurality of apertures are defined through the splitter.

37. The method of claim 35, wherein the apertures are substantially circular.

38. The method of claim 35, wherein the splitter is arranged so as approximately to bisect an angle between the first side and the second side.

39. The method of claim 21, further comprising cracking higher hydrocarbons in diesel exhaust using a diesel oxidation catalyst disposed between the exhaust gas source and the tapered inlet manifold.

40. The method of claim 21, wherein each hot-side heat exchanger includes at least one threaded rod sealingly coupling the hot-side heat exchanger to the inlet manifold.
